(19) United States
(12) Patent Application Publication
(10) Pub. No.: US 2023/0326817 A1
(43) Pub. Date: Oct. 12, 2023

(54) SEMICONDUCTOR PACKAGE AND ELECTRONIC DEVICE HAVING THE SAME

(71) Applicant: DENSO CORPORATION, Kariya-city (JP)

(72) Inventors: Noboru NAGASE, Kariya-city (JP); Ippei KAWAMOTO, Kariya-city (JP); Toshihiro FUJITA, Kariya-city (JP); Atsushi SAITO, Kariya-city (JP); Hideki KABUNE, Kariya-city (JP)

(21) Appl. No.: 18/334,625

(22) Filed: Jun. 14, 2023

Related U.S. Application Data
(63) Continuation of application No. PCT/JP2021/044454, filed on Dec. 3, 2021.

(30) Foreign Application Priority Data
Dec. 23, 2020 (JP) 2020-213686

(51) Int. Cl. H01L 23/08; H01L 23/14; H01L 23/29; H01L 23/495

(52) U.S. Cl. CPC H01L 23/08; H01L 23/14; H01L 23/293; H01L 23/49568

(57) ABSTRACT

A semiconductor package includes semiconductor elements, a lead frame, a crosslinked member, and sealing resin. Each of the semiconductor elements has a first surface and a second surface located on a side opposite to the first surface. The lead frame has a mounting portion and a connected portion. At least one of the semiconductor elements mounts on the mounting portion. The connected portion is separated from the mounting portion. The crosslinked member is connected to the second surface of at least one of the semiconductor elements and the connected portion to electrically connect at least one of the semiconductor elements and the connected portion. The sealing resin is electrically insulated and covers a portion of the lead frame, the semiconductor elements and the crosslinked member. At least one of the semiconductor elements is different from another one of the semiconductor elements in element size or power consumption.

### CROSS REFERENCE TO RELATED APPLICATIONS

The present application is a continuation application of International Patent Application No. PCT/JP2021/044454 filed on Dec. 3, 2021, which designated the U.S. and claims the benefit of priority from Japanese Patent Application No. 2020-213686 filed on Dec. 23, 2020. The entire disclosures of all of the above applications are incorporated herein by reference.

### TECHNICAL FIELD

The present disclosure relates to a semiconductor package and an electronic device having the semiconductor package.

### BACKGROUND

In a semiconductor package, a semiconductor element may mount on a lead frame. A heat radiation member may be connected to a top surface of the semiconductor element on a side opposite to the lead frame, and the semiconductor element may be covered by sealing resin.

### SUMMARY

The present disclosure describes a semiconductor package including a semiconductor element, a lead frame, a crosslinked member, and sealing resin, and further describes an electronic device including the semiconductor package, a circuit board, a heat radiation member, and a heat radiation layer.

### BRIEF DESCRIPTION OF DRAWINGS

FIG. 1 illustrates a top layout of a semiconductor package according to a first embodiment.

FIG. 2 is a cross-sectional view showing a cross-sectional configuration along line II-II in FIG. 1.

FIG. 3 is a cross-sectional view taken along a line III-III in FIG. 1.

FIG. 4 is a cross-sectional view that illustrates an example of an electronic device having the semiconductor package according to the first embodiment.

FIG. 5 illustrates a drive timing and a current value of each of two semiconductor elements.

FIG. 6 is an explanatory diagram that illustrates improvement of the capability of each of heat transfer and heat radiation from one of the semiconductor elements to another one of the semiconductor elements in the semiconductor package illustrated in FIG. 1.

FIG. 7 is a cross-sectional view that illustrates a semiconductor package according to a comparative example.

FIG. 8 is a cross-sectional view that illustrates an example of an electronic device adopting the semiconductor package according to the comparative example.

FIG. 9 is a graph that illustrates the characteristics of heat radiation of the semiconductor package.

FIG. 10 illustrates a top layout of a semiconductor package according to a second embodiment.

FIG. 11 illustrates a circuitry structure of the semiconductor package according to the second embodiment.

FIG. 12 illustrates a top layout of a semiconductor package according to a third embodiment.

FIG. 13 illustrates a circuitry structure of the semiconductor package according to the third embodiment.

FIG. 14 illustrates a top layout of a semiconductor package according to a fourth embodiment.

FIG. 15 illustrates a circuitry structure of the semiconductor package according to the fourth embodiment.

FIG. 16 illustrates a top layout of a semiconductor package according to a fifth embodiment.

FIG. 17 is a cross-sectional view taken along a line XVII-XVII in FIG. 16.

FIG. 18 is a cross-sectional view taken along a line XVIII-XVIII in FIG. 16.

FIG. 19 illustrates a top layout of a semiconductor package according to a sixth embodiment.

FIG. 20 illustrates a top layout of a semiconductor package according to a seventh embodiment.

FIG. 21 illustrates a top layout of a semiconductor package according to an eighth embodiment.

FIG. 22 illustrates a top layout of a semiconductor package according to modification of the eighth embodiment.

FIG. 23 illustrates a top layout of a semiconductor package according to a ninth embodiment.

FIG. 24 is an arrow view that illustrates the semiconductor package as viewed in an XXIV direction in FIG. 23.

FIG. 25 illustrates a top layout of a semiconductor package according to a tenth embodiment.

FIG. 26 is a cross-sectional view that illustrates another example of an electronic device including the semiconductor package according to the embodiment.

### DETAILED DESCRIPTION

A semiconductor package may efficiently radiate heat from a top surface of a semiconductor element by exposing a heat radiation member connected to the top surface of the semiconductor element from the sealing resin and connecting the heat radiation element to an external cooler. The semiconductor package may be applied to, for example, an in-vehicle system adapted to a vehicle such as an automobile.

In the above-mentioned type of semiconductor package, when the heat radiation member exposed to outside is connected to the cooler, it may be required to arrange material such as heat radiation gel with a predetermined thickness or larger having relatively high thermal conductivity between the heat radiation member and the cooler to ensure insulation.

In a case where insulated material with larger thickness is arranged between the heat radiation member and the cooler, the capability of heat radiation may decrease even though the insulation may be ensured. In the above-mentioned semiconductor package, since a part of the heat radiation member is exposed from the sealing resin, a short circuit may occur if conductive foreign substance such as a metal piece or moisture is adhered even though the insulated material has a predetermined thickness or larger.

The miniaturization of an electronic device and a semiconductor package adopted in the electronic device has been demanded in an in-vehicle system. In a case of miniaturize the semiconductor package, the capability of heat radiation may decrease and the area of heat radiation may also decrease. Therefore, both of miniaturization and heat radiation are demanded in the semiconductor package.

According to a first aspect of the present disclosure, a semiconductor package includes multiple semiconductor elements, a lead frame, a crosslinked member, and sealing resin. The lead frame includes a mounting portion and a connected portion. A first surface of at least one of the multiple semiconductor elements is connected to the mounting portion. The connected portion is separated from the mounting portion. The crosslinked member is connected to a second surface of at least one of the semiconductor elements and the connected portion. The crosslinked member electrically connects at least one of the semiconductor elements and the connected portion. The second surface is located on a side opposite to the first surface. The sealing resin is electrically insulated, and covers a portion of the lead frame, the semiconductor elements and the crosslinked member. At least one of the semiconductor elements is different from another one of the semiconductor elements in element size or power consumption during the drive of the semiconductor package. The sealing resin has a surface layer portion covering at least the crosslinked member and has thermal conductivity being equal to or larger than 2.2 watts per meter-kelvin (W/m·K).

According to the above structure, the semiconductor package has a top-surface heat radiation structure in which the first surface of one or more of the semiconductor elements mounts on the mounting portion, and the crosslinked member is connected to the second surface of one or more of the semiconductor elements is connected. In the semiconductor package, the crosslinked member is covered by the sealing resin being electrically insulated. The surface layer portion of the sealing resin covering the crosslinked member has thermal conductivity of 2.2 W/m·K or more. In the semiconductor package, since the crosslinked member is covered by the sealing resin being electrically insulated and is not exposed to outside, it is possible to ensure the capability of insulation between the crosslinked member as a heat radiation unit and outside. In addition, sine the surface layer portion of the sealing resin for covering the crosslinked member is 2.2 W/m·K or more, it is possible to ensure the capability of heat radiation. Since at least one of the semiconductor elements is different from other of the semiconductor elements in element size or power consumption during the drive of the semiconductor package, the amount of heat generation among the semiconductor elements becomes uneven and the effective area in the semiconductor package for heat diffusion increases. Therefore, the capability of heat radiation is enhanced. Even if the semiconductor package is miniaturized, the semiconductor package has a structure capable of ensuring both the capability of insulation and the capability of heat radiation at the top surface.

According to a second aspect of the present disclosure, a semiconductor package includes a semiconductor element, a lead frame, a crosslinked member, and sealing resin. The semiconductor element is a rectangular plate, and has a first surface and a second surface located on a side opposite to the first surface. The lead frame has a mounting portion and a connected portion being separated from the mounting portion. The semiconductor element mounts on the mounting portion. The first surface of the semiconductor element is connected to the mounting portion. The crosslinked member is connected to the second surface and the connected portion, and electrically connects the semiconductor element and the connected portion. The sealing resin is electrically insulated, and covers a portion of the lead frame, the semiconductor element, and the crosslinked member. The crosslinked member has a larger width than the semiconductor element. The crosslinked member is disposed to cover at least two of corner portions of the semiconductor element adjacent to each other. The sealing resin has a surface layer portion covering at least the crosslinked member and having thermal conductivity of 2.2 watts per meter-kelvin or larger.

According to the above structure, the semiconductor package has a top-surface heat radiation structure in which the first surface of the semiconductor element mounts on the mounting portion, and the crosslinked member is connected to the second surface of the semiconductor element is connected. In the semiconductor package, the crosslinked member is covered by the sealing resin being electrically insulated. The surface layer portion of the sealing resin covering the crosslinked member has thermal conductivity of 2.2 W/m·K or larger. In the semiconductor package, since the crosslinked member is covered by the sealing resin being electrically insulated and is not exposed to outside, it is possible to ensure the capability of insulation between the crosslinked member as a heat radiation unit and outside. In addition, since the surface layer portion of the sealing resin for covering the crosslinked member is 2.2 W/m·K or more, it is possible to ensure the capability of heat radiation. Since it is possible to ensure the capability of insulation between the crosslinked member and outside through the sealing resin, it is possible to enlarge the area of the crosslinked member than the area of the semiconductor element and to enlarge the effective area for heat radiation. Even if the semiconductor package is miniaturized, the semiconductor package has a structure capable of ensuring both of the capability of insulation and the capability of heat radiation at the top surface.

According to a third aspect of the present disclosure, an electronic device has a semiconductor package, a circuit board, a heat radiation member, and a heat radiation layer. The semiconductor package includes multiple semiconductor elements, a lead frame, a crosslinked member, and sealing resin. The multiple semiconductor elements are different in element size or power consumption during the drive of the semiconductor package. The lead frame has a mounting portion and a connected portion. A first surface of at least one semiconductor element is connected to the mounting portion, and the connected portion is separated from the mounting portion. The crosslinked member is connected to the second surface of at least one semiconductor element and the connected portion of the lead frame, and electrically connects the semiconductor element and the connected portion. The second surface is located on a side opposite to the first surface. The sealing resin is electrically insulated, and covers the multiple semiconductor elements and the crosslinked member. The sealing resin has a surface layer portion covering at least the crosslinked member and having thermal conductivity of 2.2 watts per meter-kelvin or larger. The semiconductor package mounts on the circuit board. The heat radiation member is arranged on a side opposite to the circuit board with the semiconductor package sandwiched between the heat radiation member and the circuit board. The heat radiation member diffuses heat to outside. The heat radiation layer is arranged at a top surface of the sealing resin, and is in contact with the heat radiation member. The top surface of the sealing resin is a surface on a side covering the crosslinked member and facing the heat radiation member.

According to the electronic device described above, the semiconductor package having the top-surface heat radiation structure is connected to the heat radiation member through the heat radiation layer. In the semiconductor package, the crosslinked member connected to the semiconductor element is covered by the sealing resin, and the thermal conductivity of the surface layer portion as a portion of the sealing resin for covering the crosslinked member is 2.2 W/m·K or larger. In the semiconductor package, the crosslinked member is electrically insulated and is covered by the surface layer portion having predetermined thermal conductivity or larger, and the crosslinked member is not exposed to outside. Therefore, even though the semiconductor package is miniaturized, it is possible to ensure both of the capability of insulation and the capability of heat radiation at the top surface of the semiconductor package. In the electronic device having the semiconductor package, it is possible to reduce the thickness of the heat radiation layer arranged in gap between the semiconductor package and the heat radiation member so that the thermal resistance is reduced. Therefore, the capability of heat radiation is enhanced. Since the electronic device ensures the capability of insulation between the top surface of the semiconductor package and other members, the reliability is also enhanced.

Embodiments of the present disclosure will be described below with reference to the drawings. In the following embodiments, the same reference numerals are assigned to parts that are the same or equivalent to each other.

### First Embodiment

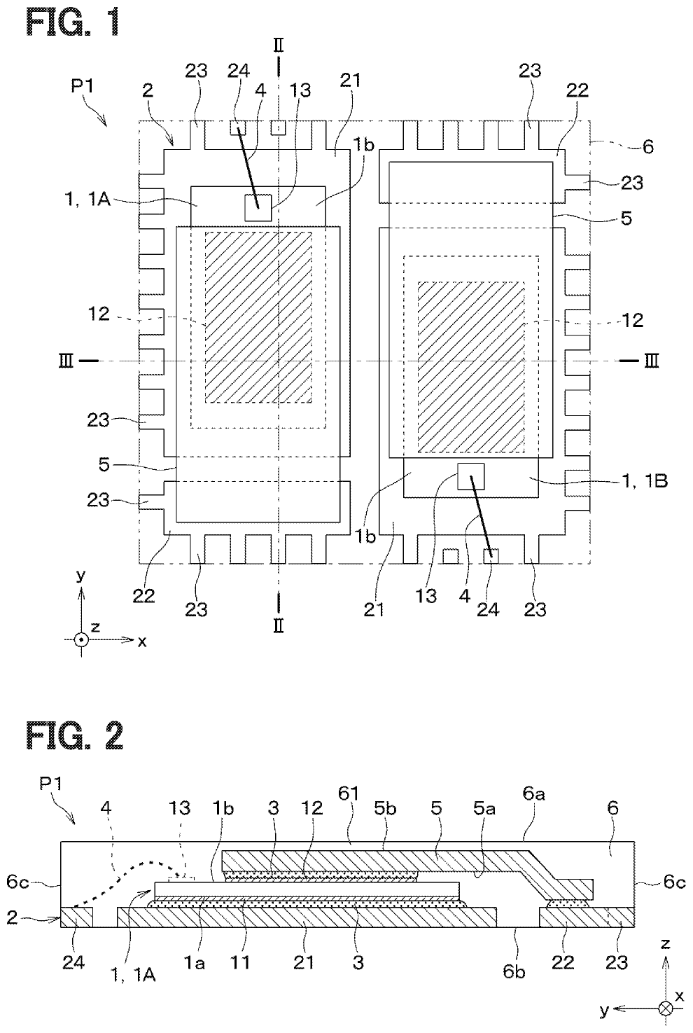

A semiconductor package P1 according to a first embodiment will be described with reference to FIGS. 1 to 3. The semiconductor package P1 may be adapted to a vehicle such as an automobile, and may be preferably to be adopted in drive control of various in-vehicle components. However, the semiconductor package P1 may not be limited to the above situations.

In FIG. 1, the outline of sealing resin 6 is indicated by a two-dot chain line; a portion of the outline of an internal structure covered by the sealing resin 6 that is also covered by a crosslinked member 5 is indicated by a broken line, and other portions are indicated by a solid line. Although FIG. 1 does not illustrate a cross-sectional view, a second electrode 12 of a semiconductor element 1 is hatched for easy understanding. In FIG. 2, a third electrode 13 and a wire 4 located on another cross-sectional view are indicated by a broken line for easier understanding of the mounting state of the semiconductor element 1.

Hereinafter, for convenience of explanation, as shown in FIG. 1, a direction along a left-right direction in the view is referred to as an “x direction”, and a direction orthogonal to the x direction in the view is referred to as a “y direction”. Further, a normal direction to an x-y plane including the x direction and y direction is referred to as a “z direction”. The x, y, and z directions in the view in FIG. 2 and subsequent figures correspond to the x, y, and z directions in FIG. 1, respectively. As illustrated in FIG. 1, a view of the semiconductor package P1 in the z direction may also be referred as a “top view”.

(Semiconductor Package)

As illustrated in, for example, FIG. 1, the semiconductor package P1 according to the present embodiment includes two semiconductor elements 1, a lead frame 2, a wire 4, two crosslinked members 5 and sealing resin 6. The lead frame 2 includes a mounting portion 21 and a connected portion 22. The sealing resin 6 covers the two semiconductor elements 1, the lead frame 2, the wire 4, the two crosslinked members 5. The semiconductor package P1 is a 2-in-1 structure in which the two semiconductor elements 1 are covered by the sealing resin 6. As illustrated in, for example, FIGS. 1, 2, the semiconductor package P1 is a Quad Flat Non-leaded Package (QFN) structure. In the QFN structure, the lead frame 2 is located inside the outline of the sealing resin 6, and a surface of the lead frame 2 on a side opposite to the semiconductor element 1 is exposed from the sealing resin 6. In the semiconductor package P1, two semiconductor elements 1 respectively mount on mounting portions 21 of the lead frame 2 arranged independently, and the two semiconductor elements 1 are electrically independent.

For example, a metal-oxide-semiconductor field effect transistor (MOSFET), an insulated-gate bipolar transistor (IGBT), an RC-IGBT may be adopted as the semiconductor element 1. The IGBT and a diode are integrated in the RC-IGBT. The semiconductor element 1 has, for example, silicon (Si) or silicon carbide (SiC) as a main component, and is manufactured by a semiconductor process. The following describes that the semiconductor element 1 is the power MOSFET.

For example, as illustrated in FIG. 2, the semiconductor element 1 is a rectangular plate whose longitudinal direction is the y direction. The semiconductor element 1 has a first electrode 11 at a first surface 1a closer to the mounting portion 21, and has the second electrode 12 and a third electrode 13 at a second surface 1b on a side opposite to the first surface 1a. The first electrode 11 of the semiconductor element 1 is a drain electrode. The second electrode 12 of the semiconductor element 1 is a source electrode. The third electrode 13 of the semiconductor element 1 is a gate electrode. The semiconductor element 1 mounts on the mounting portion 21 of the lead frame 2 through a joint member 3 made of conductive bonding material such as solder.

As shown in FIG. 1, the left one of the two semiconductor elements 1 in the x direction is referred to as a “first semiconductor element 1A”, and the right one of the two semiconductor elements 1 in the x-direction is referred to as a “second semiconductor element 1B”. As illustrated in FIG. 2, a surface located above the crosslinked member 5 in the z direction as a portion of the exterior surface of the sealing resin 6 covering the crosslinked member 5 is referred to as a “top surface 6a”, a surface as a portion of the exterior surface of the sealing resin 6 on a side opposite to the top surface 6a is referred to as “bottom surface 6b”, and a surface as a portion of the exterior surface of the sealing resin 6 connecting the top surface 6a and the bottom surface 6b is referred to as a “side surface 6c”.

The semiconductor elements 1A, 1B respectively mount on different mounting portions 21 of the lead frame 2. The first electrode 11 and the mounting portion 21 are electrically connected. In each of the semiconductor elements 1A, 1B, the crosslinked member 5 is connected to the second electrode 12. Each of the semiconductor elements 1A, 1B is electrically connected to the connected portion 22 arranged separately from the mounting portion 21 of the lead frame 2 through the crosslinked member 5. In each of the semiconductor elements 1A, 1B, the third electrode 13 is exposed from the crosslinked member 5, and the wire 4 is connected to the third electrode 13. As illustrated in, for example, FIG. 1, the semiconductor elements 1A, 1B are arranged such that, in a top view, one of the third electrodes 13 is located at a top side in the y direction, and another one of the third electrodes 13 is located at a bottom side in the y direction. In other words, both of the third electrodes 13 are in a point symmetrical arrangement.

The semiconductor elements 1A, 1B respectively have different amount of heat generation at a time of driving the semiconductor package P1. In other words, a predetermined temperature gradient or larger occurs between the semiconductor elements 1A, 1B. For example, in a situation where the semiconductor elements 1A, 1B are not driven at the same time; or the semiconductor elements 1A, 1B are different in size; or the semiconductor elements 1A, 1B are different in power consumption at a time of driving the semiconductor elements 1A, 1B, the semiconductor elements 1A, 1B do not have the same amount of heat generation at the same time. Thus, the heat radiation is enhanced by efficiently transferring the heat between the semiconductor elements 1A, 1B through the sealing resin 6.

The lead frame 2 is made of, for example, metal material such as copper (Cu), iron (Fe) or an alloy thereof. The lead frame 2 has the mounting portion 21, the connected portion 22 and multiple terminal portions 23. The semiconductor element mounts on the mounting portion 21. The connected portion 22 is arranged separately from the mounting portion 21. Each of the terminal portions 23 protrudes from the mounting portion 21 or the connected portion 22. Each of the terminal portions 23 may also be referred to as a first terminal portion 23. The lead frame 2 further includes a second terminal portion 24 separated from the mounting portion 21 and the connected portion 22. For example, in the lead frame 2, the mounting portion 21, the connected portion 22 and the second terminal portion 24 are connected by, for example, a tie bar (not shown) until the sealing resin 6 is molded. By cutting and removing the connecting part after the molding of the sealing resin 6, the mounting portion 21, the connected portion 22 and the second terminal portion 24 are finally separated. In the present embodiment, the lead frame 2 includes two mounting portions 21 and two connected portions 22, which are spaced from each other and independent of each other.

The semiconductor element 1 mounts on the mounting portion 21. The mounting portion 21 includes multiple first terminal portions 23. For example, as illustrated in FIG. 1, each of the first terminal portions 23 protrudes to a side of the sealing resin 6 adjacent to the outline of sealing resin 6. In the first embodiment, the first terminal portion 23 of the mounting portion 21 functions as a drain terminal, and is exposed outward at the bottom surface 6b and the side surface 6c of the sealing resin 6. Two semiconductor elements 1 respectively mount on two mounting portions 21.

In the following, one of two mounting portions 21 on which the first semiconductor element 1A mounts is referred to as a “first mounting portion 21”, and another one of two mounting portions 21 on which the second semiconductor element 1B mounts is referred to as a “second mounting portion 21”.

The connected portion 22 is a member paired with the mounting portion 21, and includes multiple first terminal portions 23 as similar to the mounting portion 21. The connected portion 22 is paired with the adjacent mounting portion 21 in, for example, the y direction. The connected portion 22 is spaced apart from the mounting portion 21, and is connected to an end of the crosslinked member 5. The connected portion 22 is electrically connected, through the crosslinked member 5, to the second electrode 12 of the first semiconductor element 1 mounting on the mounting portion 21 paired with the connected portion 22. In the present embodiment, the first terminal portion 23 of the connected portion 22 functions as a source terminal, and is exposed outward at the bottom surface 6b and the side surface 6c of the sealing resin 6.

For example, as illustrated in FIG. 1, the first terminal portions 23 are provided at the mounting portion 21 or the connected portion 22. For example, the first terminal portions 23 are arranged parallel to each other with a gap therebetween.

For example, the second terminal portion 24 is arranged at a position different from the mounting portion 21 and the connected portion 22, and is a member electrically connected to the third electrode 13 of the semiconductor element 1 through the wire 4. In the present embodiment, the second terminal portion 24 functions as a gate terminal, and is exposed to outside at the bottom surface 6b and the side surface 6c of the sealing resin 6. For example, as illustrated in FIG. 2, the second terminal portion 24 is partly exposed form the sealing resin 6, and is connected to, for example, an external circuit board.

In the lead frame 2, both of the first mounting portion 21 and the connected portion 22 paired with the first mounting portion 21 and both of the second mounting portion 21 and the connected portion 22 paired with the second mounting portion 21 are arranged in parallel in the x direction, and are oriented in opposite directions in the y direction. In other words, the above-mentioned components are arranged in a point symmetric pattern. In the semiconductor package P1, the arrangement of the source terminal and the drain terminal in the y direction at the circuit part on the left side in the x direction is opposite to the arrangement of the source terminal and the drain terminal in the y direction at the circuit part on the right side in the x direction.

The joint member 3 is made of arbitrary conductive bonding material such as solder, and electrically connects each configuration elements of the semiconductor package P1.

The wire 4 is made of conductive material such as gold (Au). For example, the wire 4 is connected to the third electrode 13 of the semiconductor element 1 and the second terminal portion 24 through wire bonding so as to electrically connect the above-mentioned components.

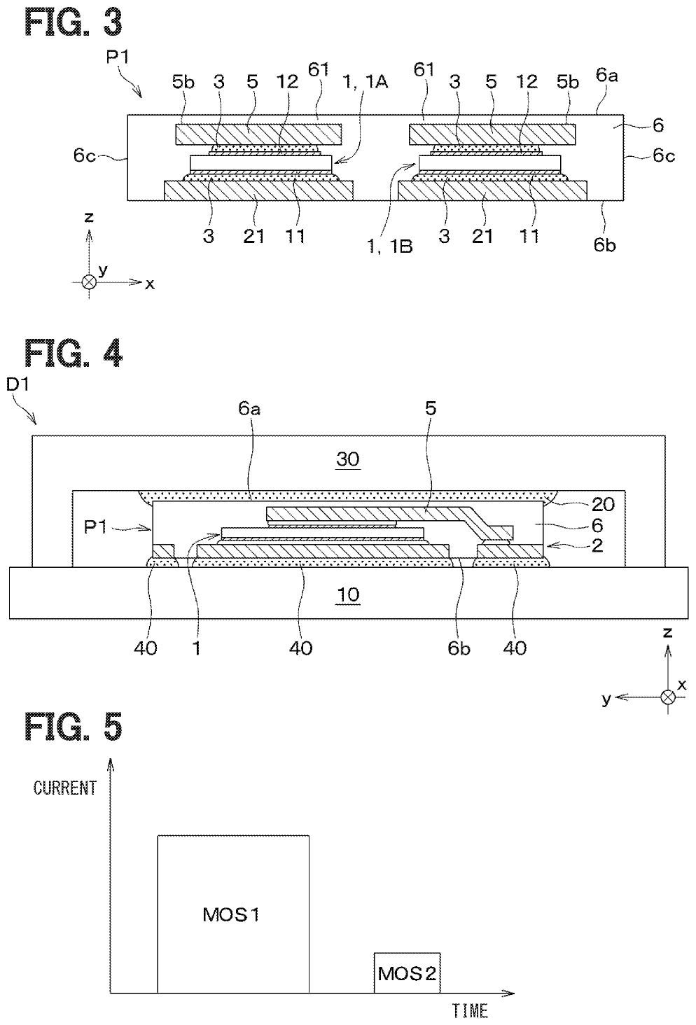

For example, the crosslinked member 5 may contain arbitrary conductive material such as metal material as a main component. The metal material may be, for example, Cu, Fe, or an alloy of Cu and Fe. The crosslinked member 5 is a connecting member that bridges the semiconductor element 1 and a portion of the lead frame 2, and electrically connects the above-mentioned components. The crosslinked member 5 may also be referred to as a clip or a bridging member. For example, as illustrated in FIGS. 1 and 3, the crosslinked member 5 has a width larger than the width of the semiconductor element 1 in the x direction, and is joined to the second electrode 12 through the joint member 3.

For example, the crosslinked member 5 is arranged to cover all other regions of the second surface 1b of the semiconductor element 1 except a predetermined region having the third electrode 13 in the top view. In other words, the crosslinked member 5 covers two corner portions of the second surface 1b of the semiconductor element 1 on a side opposite to the third electrode 13, and easily diffuses heat outward at a time of driving the semiconductor element 1. The crosslinked member 5 is entirely covered with the sealing resin 6 except the portion at which the first semiconductor element 1 and the lead frame 2 are connected, and is not exposed to outside. As illustrated in FIG. 2, the crosslinked member 5 has a connection surface 5a on the semiconductor element 1 and the connected portion 22 side, and has an opposite surface 5b on a side opposite to the connection surface 5a. The opposite surface 5b is entirely covered with the sealing resin 6, and insulated from outside by the sealing resin 6.

The surface of the mounting portion 21 on which the semiconductor element 1 mounts is referred to as a mounting surface. The crosslinked member 5 has a height being a dimension in a direction normal to the mounting surface, and the height of the crosslinked member 5 is the largest compared to other members. In other words, the crosslinked member 5 is arranged closest to the top surface 6a among the members covered by the sealing resin 6. Therefore, it is possible to minimize a surface layer portion 61 of the sealing resin 6 as a portion covering the crosslinked member 5, and it is advantageous for radiating the heat outside from the crosslinked member 5.

The sealing resin 6 has resin material and a filler. The resin material such as epoxy resin is electrically insulated. The filler has larger thermal conductivity than the resin material. For example, inorganic particles such as alumina may be adopted as the filler. The sealing resin 6 is formed, for example, by injection molding using a mold. The sealing resin 6 covers the semiconductor element 1, a portion of the lead frame 2, the joint member 3, the wire 4, and the crosslinked member 5. The sealing resin 6, has, for example, the top surface 6a and the bottom surface 6b that are flat surfaces along the x-y plane. Other members of the semiconductor package P1 are not exposed at the top surface 6a of the sealing resin 6, and the capability of electrical insulation at the top surface 6a is ensured.

The sealing resin 6 is electrically insulated and has the thermal conductivity with a predetermined value or larger through the adjustment of the amount of filler and material. For example, as illustrated in FIGS. 2, 3, the sealing resin 6 has a portion being the surface layer portion 61 that covers at least the surface of the crosslinked member 5 that is located on the uppermost side in the z direction. The thermal conductivity of the surface layer portion 61 is 2.2 watts per meter-kelvin (W/m·K) or larger. In the present embodiment, the sealing resin 6 has the thermal conductivity being 2.2 W/m·K or larger in the entire region including the surface layer portion 61. The following describes the details of the thermal conductivity of the sealing resin 6 and the thickness of the surface layer portion 61.

The above describes the structure of the semiconductor package P1 according to the present embodiment. When the semiconductor package P1 is driven, since a temperature gradient occurs between two semiconductor elements 1, the capability of heat radiation inside the package is further enhanced by heat diffusion from one of the semiconductor elements 1 that has a higher temperature to another one of the semiconductor elements 1 that has a lower temperature.

(Electronic Device)

The following describes an example of an electronic device D1 adopting the semiconductor package P1 with reference to FIGS. 4 to 6.

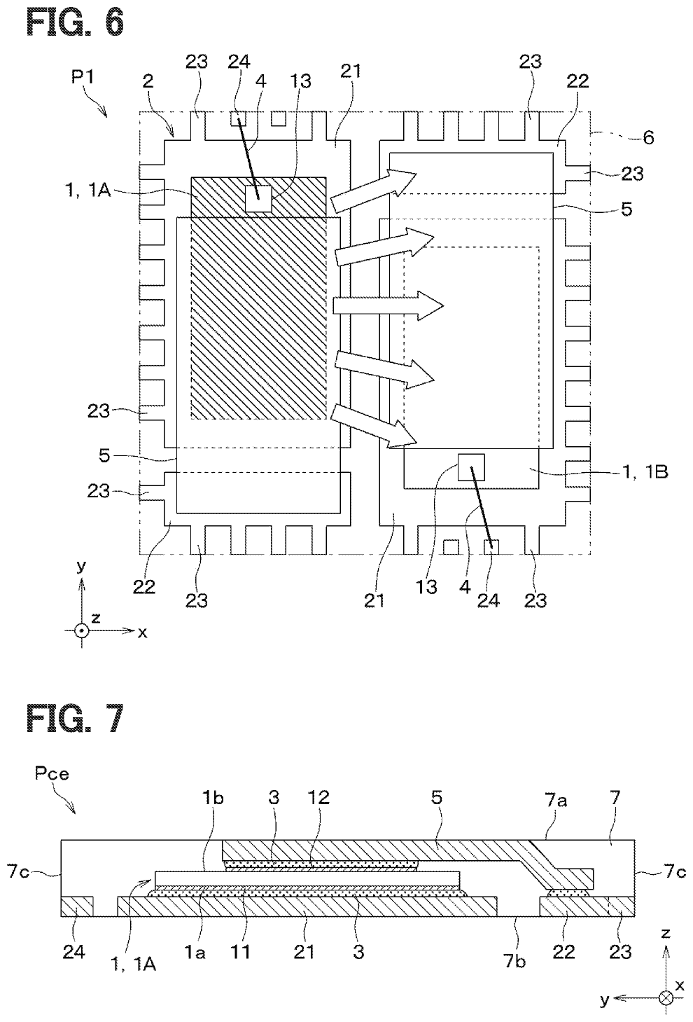

In FIG. 6, as similar to FIG. 1, the outline of sealing resin 6 is indicated by a two-dot chain line; a portion of the outline of an internal structure covered by the sealing resin 6 that is also covered by a crosslinked member 5 is indicated by a broken line, and other portions are indicated by a solid line. Although FIG. 6 does not illustrate a cross-sectional view, the first semiconductor element 1A is hatched, and the thermal diffusion is indicated by a white-blank arrow.

For example, as illustrated in FIG. 4, the electronic device D1 includes a circuit board 10, the semiconductor package P1, a heat radiation layer 20, and a heat radiation member 30. In the electronic device D1, the semiconductor package P1 mounts on the circuit board 10 through joint material 40 made of, for example, solder. The wiring (not shown) of the circuit board 10 and terminals of the lead frame 2 exposed to the bottom surface 6b are connected, so that the electrical connection to the semiconductor element 1 can be made.

The circuit board 10 is, for example, a printed circuit board, and has the wiring or pads (not shown) made of conductive material on the electrically insulated board.

The heat radiation layer 20 is, for example, a heat radiation gel that is electrically insulated and has thermal conductivity equal to or larger than a predetermined value. The top surface 6a of the semiconductor package P1 faces the heat radiation member 30. The heat radiation layer 20 is arranged at the top surface 6a to fill the gap between the heat radiation member 30 and the top surface 6a. The heat radiation layer 20 thermally connects the semiconductor package P1 and the heat radiation member 30. The thickness of the heat radiation layer 20 in the z direction is made smaller as compared with a comparative example in which the crosslinked member 5 is exposed to outside, since the crosslinked member 5 of the semiconductor package P1 is covered by the sealing resin 6.

The heat radiation member 30 is a member that has a heat radiation fin, and is made of metal material having higher thermal conductivity. For example, the heat radiation member 30 is, for example, a housing for an external load such as a motor driven by, for example, the operation of the semiconductor element 1. The heat radiation member 30 is thermally coupled with the semiconductor package P1 through the heat radiation layer 20, and serves to release the heat of the semiconductor package P1 to outside. For example, as illustrated in FIG. 4, the heat radiation member 30 has a recess covering the semiconductor package P1, and mounts on the circuit board 10 outside the recess.

The above is an example that describes the structure of the electronic device D1. For example, the electronic device D1 is controlled that two semiconductor elements 1 of the semiconductor package P1 are not driven at the same time, so that the heat diffusion inside the package is efficiently performed while the heat of the semiconductor element 1 is emitted to outside through the heat radiation layer 20 and the heat radiation member 30.

For example, as shown in FIG. 5, the first semiconductor element 1A (MOS1 in FIG. 5) and the second semiconductor element 1B (MOS2 in FIG. 2) are controlled to be driven by energization patterns with different energization timings and current values. For example, in a case of the driving pattern shown in FIG. 5, the first semiconductor element 1A has larger amount of heat generation than the second semiconductor element 1B, and the temperature gradient occurs between the semiconductor elements 1A and 1B.

For example, as illustrated in FIG. 6, in the semiconductor package P1, the first semiconductor element 1A has a higher temperature than the second semiconductor element 1B, and the heat diffuses from the first semiconductor element 1A to the second semiconductor element 1B. In the present embodiment, since the thermal conductivity of the sealing resin 6 is larger than or equal to 2.2 W/m·K, the thermal conduction between the first semiconductor elements 1A and 1B and the heat diffusion inside the semiconductor package P1 are efficiently performed.

The drive pattern of each of two semiconductor elements 1 is not only limited to the example shown in FIG. 5. It is possible that only the energization timings may be different; only the current values may be different; or the magnitude relation of the current values may be reversed. In a case where two semiconductor elements 1 are different in size, the heat concentration occurs in the smaller semiconductor element even though the operation patterns of two semiconductor elements 1 are identical. A difference occurs in the degree of temperature rise around the semiconductor element 1. The heat diffusion occurs from a higher temperature side to a lower temperature side.

In any of the above situations, in the semiconductor package P1, a temperature difference occurs between two semiconductor elements 1, and the heat is diffused to a region of the semiconductor element 1 at a low temperature side. Thus, an effective area of the heat diffusion increases so that the heat radiation is enhanced. As a result, the heat of the semiconductor element 1 is diffused to the portion other than the surface layer portion 61 on the top surface 6a of the semiconductor package P1, and the efficiency of heat radiation member 30 through the heat radiation layer 20 is also substantially enhanced. Therefore, the electronic device D1 has enhanced capability of heat radiation.

In the electronic device D1, the semiconductor package P1 mounting on the circuit board 10 is the Quad Flat Package (QFN) structure. Therefore, the usage area of the semiconductor package P1 in the circuit board 10 becomes smaller so that it is possible to efficiently use the circuit board 10.

The electronic device D1 has a larger junction area between the circuit board 10 and the semiconductor package P1, and the distance between the circuit board 10 and the semiconductor package P1 is smaller than that of the package structure having a terminal protruding outside the QFP structure. Therefore, the electronic device D1 can also attain the effect of releasing the heat of the circuit board 10 efficiently through the semiconductor package P1.

For example, in a case where a large current is generated in the circuit board 10, the circuit board 10 also generates heat. When electronic components mount on both sides of the circuit board 10 for the purpose of miniaturization or the like, the heat generation becomes more remarkable. When the semiconductor package P1 with enhanced capability of heat radiation, the circuit board 10 is thermally connected to the heat radiation member 30 having larger thermal conductivity than the circuit board 10 even through the semiconductor package P1. The circuit board 10 can release the heat to the heat radiation member 30 through the semiconductor package P1, and can substantially increase the contact area with the heat radiation member 30. Therefore, the electronic device D1 can also attain the enhanced capability of heat radiation of the circuit board 10 through the semiconductor package P1.

The electronic device D1 is not only limited to the above-mentioned structure. The electronic device D1 may have a structure in which the semiconductor package P1 is directly fixed to the heat radiation member 30; however, in this case, the circuit board 10 and the semiconductor package P1 are thermally isolated. In the electronic device D1, the semiconductor package P1 may mount on the circuit board 10 to enhance the capability of heat radiation of the circuit board 10.

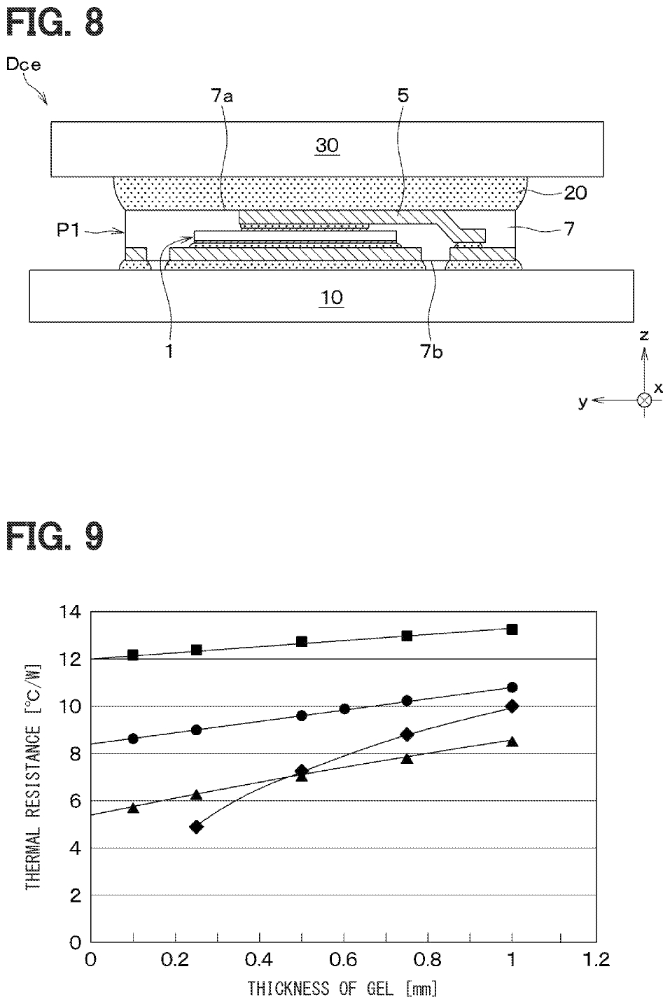

The following describes the insulation of the top surface 6a of the semiconductor package P1 and its advantageous effect with reference to a comparative example illustrated in each of FIGS. 7, 8.

Firstly, a semiconductor package P2 according to the comparative example and an electronic device Dce using the semiconductor package P2 will be described.

FIG. 7 is a cross-sectional view showing the semiconductor package Pce according to the comparative example, and corresponds to the cross-sectional view of FIG. 2. FIG. 8 illustrates an example of the electronic device Dce having the semiconductor package Pce according to the comparative example, and corresponds to the cross-sectional view of FIG. 4.

The semiconductor package Pce according to the comparative example is different from the semiconductor package P1 such that, in the semiconductor package Pce, the crosslinked member 5 is exposed from sealing resin 7 and the thermal conductivity of the sealing resin 7 may be 2.2 W/m·K or smaller. As illustrated in FIG. 7, the semiconductor package Pce has a first surface 7a on a top side of the sealing resin 7 in the z direction, and has a second surface 7b on a side opposite to the first surface 7a. In the semiconductor package Pce, the crosslinked member 5 is exposed to outside from the first surface 7a.

For example, as illustrated in FIG. 8, in the electronic device Dce according to the comparative example having the semiconductor package Pce, the semiconductor package Pce mounts on the circuit board 10 through the joint material 40, and the heat radiation layer 20 and the heat radiation member 30 stack on the semiconductor package Pce. In the semiconductor package Pce, since the crosslinked member 5 is exposed from the sealing resin 7 at the first surface 7a, the capability of insulation with the second electrode 12 of the semiconductor element 1 is not ensured. In order to ensure the capability of insulation between the semiconductor package Pce and the heat radiation member 30, it is required that the heat radiation layer 20 has a predetermined thickness or larger in the z direction.

Since the heat radiation layer 20 adopts soft insulated material such as a heat radiation gel, it is difficult to prevent hard foreign substance such as metal fragments from entering or prevent the adhesion or penetration of moisture from outside. For example, when conductive foreign substance enters the heat radiation layer 20 and is in contact with the exposed crosslinked member 5, the foreign substance may be in contact with, for example, the side surface 7c of the semiconductor package Pce and the circuit board 10 in addition to the heat radiation member 30. Therefore, a short circuit may occur in other members or between two crosslinked members 5 that may result in insulation fault. It also applies to a situation in which moisture adheres to the semiconductor package Pce. In a situation where the heat radiation member 30 is, for example, a housing for an external load such as a motor, the semiconductor package Pce and the heat radiation layer 20 are positioned in the vicinity of the movable member, and the electronic device Dce may easily have insulation fault due to contamination of foreign substance.

In the field of semiconductor packages, it has been considered to enhance the capability by making it compatible with a high voltage battery of 60 V or lower such as 48 V for an in-vehicle system. For example, when the power supply voltage becomes higher such as 24 to 48 V, the possibility of insulation fault in the electronic device Dce also becomes higher.

In order to inhibit the insulation fault, it is conceivable to reduce the exposed area of the crosslinked member 5. However, the capability of heat radiation may decrease. It is also conceivable to use a sheet-like heat radiation sheet that is harder than the heat radiation gel as the heat radiation layer 20. In this situation, although it is possible to inhibit the intrusion of foreign substance or insulation fault caused by the intrusion of foreign substance, it is not possible to inhibit the adhesion of moisture or the insulation fault caused by the adhesion of moisture.

In the electronic device Dce according to the comparative example, the thickness of the heat radiation layer 20 must be set to a predetermined value or larger to ensure the insulation, while ensuring the heat radiation without decreasing the exposed area of the crosslinked member 5. When the thickness of the heat radiation layer 20 increases, the insulation may be ensured. However, the thermal resistance of the heat radiation layer 20 increases so that the heat radiation of the semiconductor package Pce may be degraded. Therefore, in the semiconductor package Pce according to the comparative example and the electronic device Dce adopting the semiconductor package Pce, it is difficult to ensure both of the capability of heat radiation and the capability of insulation.

In contrast, in the semiconductor package P1 according to the present embodiment, the crosslinked member 5 is covered with the sealing resin 6 being electrically insulated, and is not exposed to outside. Therefore, it is possible to ensure the capability of insulation between the crosslinked member 5 and outside. In the electronic device D1 adopting the semiconductor package P1, since the crosslinked member 5 is protected by the sealing resin 6, even though foreign substance or moisture does not adhere or enter the heat radiation layer 20, the insulation fault caused by foreign substance or moisture does not occur. Since the crosslinked member 5 is insulated from outside through the sealing resin 6, the area of the crosslinked member 5 can be enlarged to enhance the heat radiation of the semiconductor element 1.

The heat radiation layer 20 is not required to be thickened to ensure the capability of insulation, and is made thinner than the comparative example. Therefore, the thermal resistance between the semiconductor package P1 and the heat radiation member 30 decreases, and the heat radiation of the semiconductor package P1 is enhanced as compared to the comparative example.

The electronic device D1 adopting the semiconductor package P1 can ensure both of the capability of insulation and the capability of heat radiation.

(Thermal Conductivity of Sealing Resin)

The following describes the thermal conductivity of the sealing resin 6 with reference to FIG. 9.

FIG. 9 illustrates each of the calculation results of the heat radiation characteristics in the semiconductor package P1 and the semiconductor package Pce in the comparative example. In FIG. 9, the horizontal axis represents the thickness of the gel [millimeter (mm)], and the vertical axis represents the thermal resistance [degree Celsius per watt (° C./W)]. In this simulation, the temperature of the top surface of the gel was fixed. The gel is, for example, electrically insulated heat radiation gel that is adopted as the heat radiation layer 20.

The comparative example has a structure in which a semiconductor package having a double-sided heat radiation structure is insulated with gel. That is, in the comparative example, a heat radiation gel being electrically insulated and having a thermal conductivity of 3 W is provided on the exposed crosslinked member 5.

Further, the thermal resistance in FIG. 9 indicates the thermal resistance in the surface layer portion 61 and the gel. In other words, the thermal resistance of the semiconductor package P1 in FIG. 9 indicates the thermal resistance of the surface layer portion 61 of the sealing resin 6 located on the crosslinked member 5. In a case where the gel, in other words, the heat radiation layer is provided on the surface layer portion 61, the thermal resistance of the semiconductor package P1 indicates the thermal resistance between the surface layer portion 61 and the gel.

The graph shown by diamond points is a graph showing the heat dissipation characteristics of the comparative example. The graph shown by triangular points is a graph showing the heat radiation characteristics of the semiconductor package P1 in a case where the thermal conductivity of the sealing resin 6 is 3 W and the thickness of the surface layer portion 61 in the z direction is 0.5 mm. The graph shown by circular points is a graph showing the heat dissipation characteristics of the semiconductor package P1 in a case where the thermal conductivity of the sealing resin 6 is 2.2 W/m·K and the thickness of the surface layer portion 61 is 0.6 mm. The graph shown by square points is a graph showing the heat radiation characteristics of the semiconductor package P1 in a case where the thermal conductivity of the sealing resin 6 is 1 W and the thickness of the surface layer portion 61 is 0.5 mm.

The gel is not provided in the semiconductor package P1 according to FIG. 9. Therefore, the thermal resistance of the semiconductor package P1 is a value at a gel thickness of 0 mm. Further, in the semiconductor package P1, as a preferable example as described above, the thermal conductivity of the sealing resin 6 is set to 2.2 W/m·K or more.

Therefore, the thermal resistance of the semiconductor package P1 is smaller than about 8° C./W, as shown in the graph of the circular points and triangular points in FIG. 9. Therefore, the semiconductor package P1 can obtain a thermal resistance equal to or lower than that of the comparative example when the thermal conductivity of the sealing resin 6 is set to 2.2 W/m·K or more. That is, the semiconductor package P1 can obtain heat radiation equal to or higher than that of the comparative example when the thermal conductivity of the sealing resin 6 is set to 2.2 W/m·K or more. Further, the semiconductor package P1 can obtain heat radiation characteristics equal to or higher than that of the comparative example when the thermal conductivity of the sealing resin 6 is set to 2.2 W/m·K or more, and the thickness of the surface layer portion 61 is set to 0.6 mm or less.

According to the present embodiment, the crosslinked member 5 is connected to each of two semiconductor elements 1, and the crosslinked member 5 has the capability of electrical insulation. In the semiconductor package P1 as a top heat radiation structure, the crosslinked member 5 is covered with the sealing resin 6 with the thermal conductivity being 2.2 W/m·K or larger. In the semiconductor package P1, the crosslinked member 5 is covered with the sealing resin 6 being electrically insulated. Therefore, the capability of electrical insulation at the top surface 6a can be ensured.

In a case where the thermal conductivity of the surface layer portion 61 of the sealing resin 6 covering at least the crosslinked member 5 is set to 2.2 W/m·K or larger, it is possible to suppress an increase in the thermal resistance of the surface layer portion. In addition, it is possible to efficiently carry out the thermal transfer to outside from the crosslinked member 5 through the sealing resin 6. Since it is possible to ensure the capability of insulation between outside and the crosslinked member 5 through the sealing resin 6, it is possible to enlarge the area of the crosslinked member 5 for the semiconductor element 1 to ensure the capability of heat radiation.

In the semiconductor package P1, the amount of heat generated during driving is uneven because two semiconductor elements 1 are not turned on at the same time, or because the energization patterns and current values are different, or because the sizes of the elements are different. Therefore, the temperature gradient is generated between two semiconductor elements 1, and an effective area of heat diffusion within the semiconductor package P1 increases to efficiently perform the thermal diffusion in the package.

The semiconductor package P1 according to the present embodiment has a structure capable of ensuring both of the capability of insulation and the capability of heat radiation at the top surface 6a even though the semiconductor package P1 is miniaturized. Since the capability of electrical insulation is ensured at the top surface 6a, for example, it can also be applied to a power supply voltage of 12-V battery or higher (for example, 24 to 48 V or 60 V or less) adopted in an in-vehicle system.

### Second Embodiment

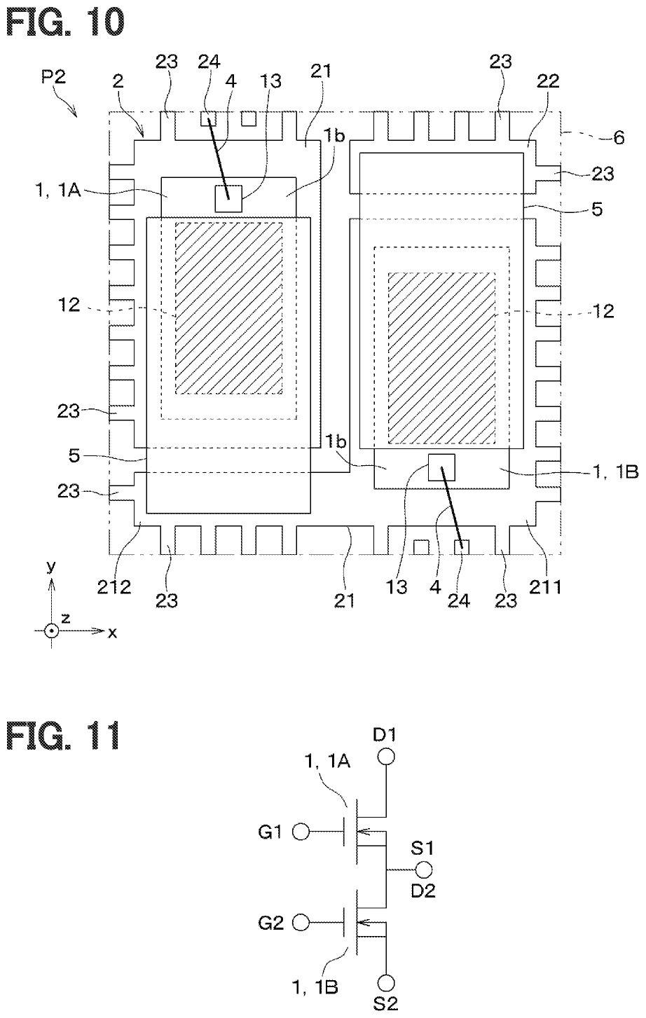

The semiconductor package P2 according to a second embodiment will be described with reference to FIGS. 10, 11.

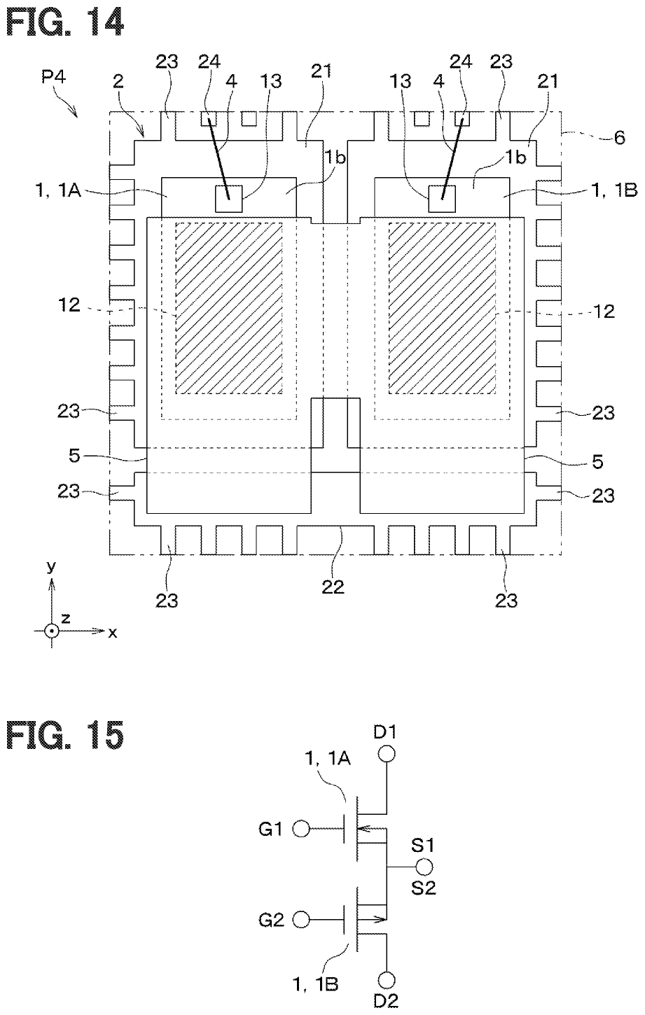

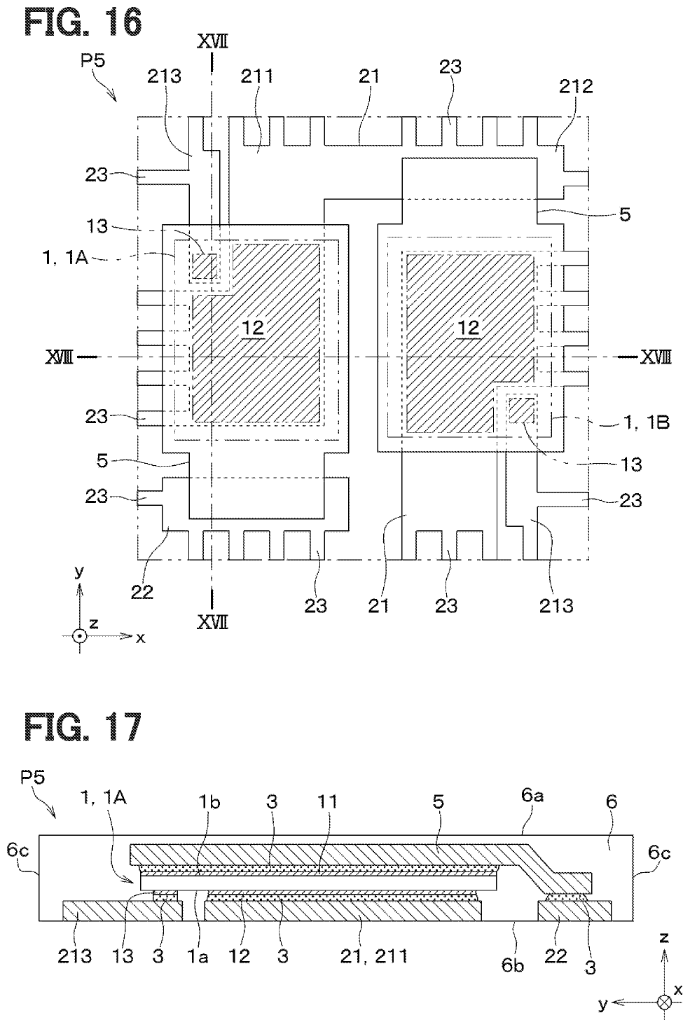

In FIG. 10, as similar to FIG. 1, the outline of the sealing resin 6 is indicated by a two-dot chain line; a portion of an internal structure covered by the sealing resin 6 that is also covered by a crosslinked member 5 is indicated by a broken line; and the outline of other portions in the internal structure is indicated by a solid line. Although FIG. 10 does not illustrate a cross-sectional view, the second electrode 12 of a semiconductor element 1 is hatched for easy understanding. The same applies to FIGS. 14 and 16.

In the semiconductor package P2 according to the present embodiment, for example, as illustrated in FIG. 10, two mutually independent mounting portions 21 are connected through the crosslinked member 5 that is connected to the first semiconductor element 1A, so that two semiconductor elements 1 are connected in series. Accordingly, the present embodiment is different from the first embodiment. Hereinafter, the difference from the first embodiment will be mainly described.

In the present embodiment, the lead frame 2 includes a first mounting portion 21, a second mounting portion 21, and a connected portion 22. The first semiconductor element 1A mounts on the first mounting portion 21. The second semiconductor element 1B mounts on the second mounting portion 21. The connected portion 22 forms a pair with the second mounting portion 21.

The second mounting portion 21 includes an element mounting portion 211 and an extension portion 212. The second semiconductor element 1B mounts on the element mounting portion 211. The extension portion 212 extends from the element mounting portion 211 to the left in the x direction. The second mounting portion 21 is arranged at a distance from the first mounting portion 21 and the connected portion 22, while the element mounting portion 211 forms a pair with the connected portion 22 and the extension portion 212 forms a pair with the first mounting portion 21. In the second mounting portion 21, the crosslinked member 5, which is connected to the first semiconductor element 1A, is connected to the extension portion 212.

For example, as illustrated in FIG. 11, the semiconductor package P2 is included in a circuit in which the semiconductor elements 1A and 1B are connected in series through the lead frame 2. In the semiconductor package P2, the heat transfer between two semiconductor elements 1 occurs through the sealing resin 6, the lead frame 2 and the crosslinked member 5. In the present embodiment, the capability of heat diffusion inside the package is enhanced as compared with the first embodiment.

In the present embodiment, the semiconductor package P2 has a circuitry structure as illustrated in FIG. 11. “D1”, “S1” and “G1” in FIG. 11 correspond to terminals respectively connected to the first electrode 11, a second electrode 12 and a third electrode 13 of the first semiconductor element 1A. “D2”, “S2” and “G2” in FIG. 11 correspond to terminals respectively connected to the first electrode 11, the second electrode 12 and a third electrode 13 of the first semiconductor element 1B.

The correspondence relation among the above-mentioned D1, D2, S1, S2, G1, G2 and the terminals are also applied to FIGS. 13, 15.

The semiconductor package P2 is included in a half-bridge circuit. In the half-bridge circuit, the first semiconductor element 1A and the second semiconductor element 1B are connected in series, and the terminal portion 23 of the second mounting portion 21 corresponding to a connecting portion between the first semiconductor element 1A and the second semiconductor element 1B serves as an output terminal. In the semiconductor package P2, for example, the terminal portion 23 (D1) of the first mounting portion 21 is connected to an external power supply (not shown), and the terminal portion 23 (S2) of the connected portion 22 is connected to a reference potential (GND). The first semiconductor element 1A is a high-side element, and the second semiconductor element 1B is a low-side element. In the present embodiment, the semiconductor elements 1A, 1B are both n-channel transistors. The first electrode 11 on the first surface 1a serves as a drain electrode, and the second electrode 12 and the third electrode 13 on the second surface 1b respectively serve as a source electrode and a gate electrode.

In other words, the terminal portion 23 of the first mounting portion 21 serves as the D1 terminal and the power supply terminal, the terminal portion 24 connected to the third electrode 13 of the first semiconductor element 1A serves as the G1 terminal, and the terminal portion 23 protruding from the extension portion 212 serves as the S1 terminal. The terminal portion 23 of the element mounting portion 211 serves as the D2 terminal and the output terminal, the terminal portion 24 connected to the third electrode 13 of the first semiconductor element 1B serves as the G2 terminal, and the terminal portion 23 of the connected portion 22 serves as the S2 terminal.

The circuitry structure of the semiconductor package P2 is, for example, the minimum configuration unit of a three-phase brushless motor drive circuit or a half-bridge circuit. The semiconductor package P2 has a circuitry structure in which the semiconductor elements 1A, 1B are not conducted at the same time. Therefore, a temperature gradient between the semiconductor elements 1A and 1B occurs during the drive of the semiconductor package P2.

When the three-phase brushless motor is driven by the semiconductor package P2, the first semiconductor element 1A being a high-side element supplies a power supply current. In the second semiconductor element 1B being a low-side element, a reflux current is generated after the cutoff of the current in the first semiconductor element 1A. In this case, for example, the duty ratio is set to 50% or more, and the electrical conduction period of the first semiconductor element 1A is longer than the electrical conduction period of the second semiconductor element 1B.

When the current in the first semiconductor element 1A is interrupted, the loss such as heat generation caused by switching occurs in a short period of time. The loss is determined by the on-resistance of the first semiconductor element 1 and the energized current. In the second semiconductor element 1B, the reflux current is generated, and the loss occurs due to a body diode. Although the loss generally increases through Vf of the diode, the loss due to the on-resistance immediately occurs through synchronous rectification, and thus the loss decreases. Subsequently, before the first semiconductor element 1A is turned on again, the first semiconductor element 1A is switched to a diode reflux. In the present embodiment, the semiconductor elements 1A, 1B are not turned on at the same time, and heat generation becomes non-uniform that results in a temperature gradient between the semiconductor elements 1A and 1B.

The second electrode 12 as the source electrode of the first semiconductor element 1A and the first electrode 11 as the drain electrode of the second semiconductor element 1B are connected through the crosslinked member 5, the extension portion 212 and the element mounting portion 211. Since the crosslinked member 5 and the lead frame 2 are made of metal material having larger thermal conductivity than the sealing resin 6, two semiconductor elements 1 are thermally coupled through the metal. The semiconductor package P2 has a structure in which the heat is transferred between two semiconductor elements 1; and the heat is diffused through the sealing resin 6 having predetermined thermal conductivity or larger. Therefore, the capability of heat radiation is enhanced.

According to the present embodiment, the same advantageous effect as that of the first embodiment is achieved. Since the semiconductor elements 1A, 1B are thermally coupled through the crosslinked member 5 and the extension portion 212, the degree of heat transfer between the semiconductor elements 1A and 1B increases so that the heat diffusion inside the package becomes more efficient. The semiconductor package P2 has enhanced capability of heat radiation as compared with the first embodiment.

### Third Embodiment

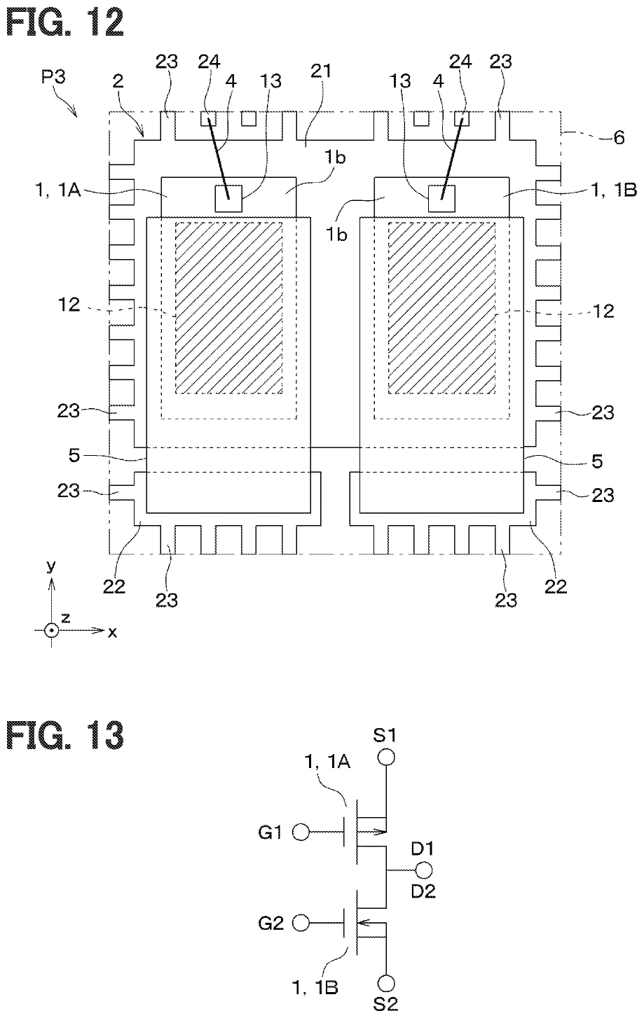

A semiconductor package P3 according to a third embodiment will be described with reference to FIGS. 12, 13.

For example, as illustrated in FIG. 12, the semiconductor package P3 according to the present embodiment is different from the first embodiment, such that the structure of the lead frame 2 and the orientation of the second semiconductor element 1B are modified in the present embodiment. Hereinafter, the difference from the first embodiment will be mainly described.

In the present embodiment, the lead frame 2 includes one mounting portion 21, two connected portions 22 and multiple second terminal portions 24. In the present embodiment, two semiconductor elements 1 mount on the mounting portion 21. Two semiconductor elements 1 are arranged in parallel such that the alignment directions of the second electrodes 12 and the third electrodes 13 are matched. The two connected portions 22 are arranged at, for example, at positions corresponding to regions of the mounting portion 21 on which the semiconductor element 1 mounts, while being spaced apart from each other.

Each of the semiconductor elements 1A and 1B has the first electrode 11 as the drain electrode at the first surface 1a, and the first surface 1a is joined to the mounting portion 21. In the semiconductor elements 1A, 1B, different crosslinked members 5 are connected to the second electrode 12 as the source electrode. The semiconductor elements 1A, 1B are respectively connected to different connected portions 22. In the semiconductor elements 1A, 1B, the wire 4 is connected to the third electrode 13 as the gate electrode. The semiconductor elements 1A, 1B are respectively connected to different second terminal portions 24. The first terminal portion 23 of the mounting portion 21 serves as a drain terminal (D1, D2), the first terminal portion 23 of the connected portion 22 serves as a source terminal (S1, S2), and the second terminal portion 24 serves as a gate terminal (G1, G2).

For example, as illustrated in FIG. 13, the semiconductor package P3 is included in a half-bridge circuit in which the mounting portion 21 being a connecting portion of the semiconductor elements 1A, 1B serves as an output terminal. In the present embodiment, the first semiconductor element 1A is a p-channel high-side transistor, and the second semiconductor element 1B is an n-channel low-side transistor. An S1 terminal of the first semiconductor element 1A serves as a power supply terminal, and an S2 terminal of the second semiconductor element serves as a ground (GND) terminal.

As similar to the second embodiment, the semiconductor package P3 has a structure in which the semiconductor elements 1A, 1B are not turned on at the same time. Accordingly, the heat generation of the semiconductor elements 1A, 1B during the drive of the semiconductor package P3 is not uniform. Since the semiconductor elements 1A, 1B mount on an identical mounting portion 21, the semiconductor elements 1A, 1B are thermally coupled through the mounting portion 21, and the heat diffusion between the elements is smooth.

According to the present embodiment, the same advantageous effect as that of each of the first and second embodiments is achieved. Since the semiconductor elements 1A, 1B are thermally coupled through the mounting portion 21 having a larger area than the crosslinked member 5, it is possible to attain enhanced capability of heat radiation as compared with the second embodiment.

### Fourth Embodiment

A semiconductor package P4 according to a fourth embodiment will now be described with reference to FIGS. 14, 15. For example, as illustrated in FIG. 14, the semiconductor package P4 according to the present embodiment is different from the first embodiment, such that the structure of each of the lead frame 2 and the crosslinked member 5 is modified in the present embodiment. Hereinafter, the difference from the first embodiment will be mainly described.

In the present embodiment, the lead frame 2 includes two mounting portions 21, one connected portion 22 and multiple second terminal portions 24. For example, as illustrated in FIG. 14, two mounting portions 21 are arranged to be separated from each other while arranged symmetrically. One connected portion 22 has a substantially rectangular shape whose longitudinal direction is a direction in which two mounting portions 21 are arranged, and is arranged to be parallel to two mounting portions 21.

As similar to the third embodiment, the semiconductor elements 1A, 1B are arranged in parallel with the electrodes 12, 13 (source, gate) arranged in the same direction, while the first electrodes 11 on the first surface 1a side are respectively joined to different mounting portions 21. A common crosslinked member 5 is connected to the second electrode 12 of each of the second surfaces 1b of the semiconductor elements 1A, 1B, and the semiconductor elements 1A, 1B are connected in series through the crosslinked member 5.

In the present embodiment, the crosslinked member 5 has a substantially U-shape in a top view, and the crosslinked member 5 is connected to each of the semiconductor elements 1A, 1B and the connected portion 22. The crosslinked member 5 is connected to one connected portion 22 at two locations.

For example, as illustrated in FIG. 15, the semiconductor package P4 is included in a half-bridge circuit in which the connected portion 22 connected by the crosslinked member 5 being a connecting portion of the semiconductor elements 1A, 1B serves as an output terminal. In the present embodiment, the first semiconductor element 1A is an n-channel high-side transistor, and the second semiconductor element 1B is a p-channel low-side transistor. A D1 terminal of the first semiconductor element 1A serves as a power supply terminal, and a D2 terminal of the second semiconductor element 1B serves as a ground (GND) terminal.

As similar to the second embodiment, the semiconductor package P4 has a structure in which the semiconductor elements 1A, 1B are not turned on at the same time. Accordingly, the heat generation of the semiconductor elements 1A, 1B during the drive of the semiconductor package P3 is not uniform. Since the common crosslinked member 5 is connected the semiconductor elements 1A, 1B, the semiconductor elements 1A, 1B are thermally coupled through the crosslinked member 5, and the heat diffusion between the elements is smooth.

According to the present embodiment, the same advantageous effect as that of each of the first and second embodiments is achieved. Since the crosslinked member 5 has a larger area so that the semiconductor elements 1A, 1B are thermally coupled, it is possible to enhance the capability of heat radiation as compared with the second embodiment.

### Fifth Embodiment

A semiconductor package P5 according to a fifth embodiment will be described with reference to FIGS. 16 to 18.

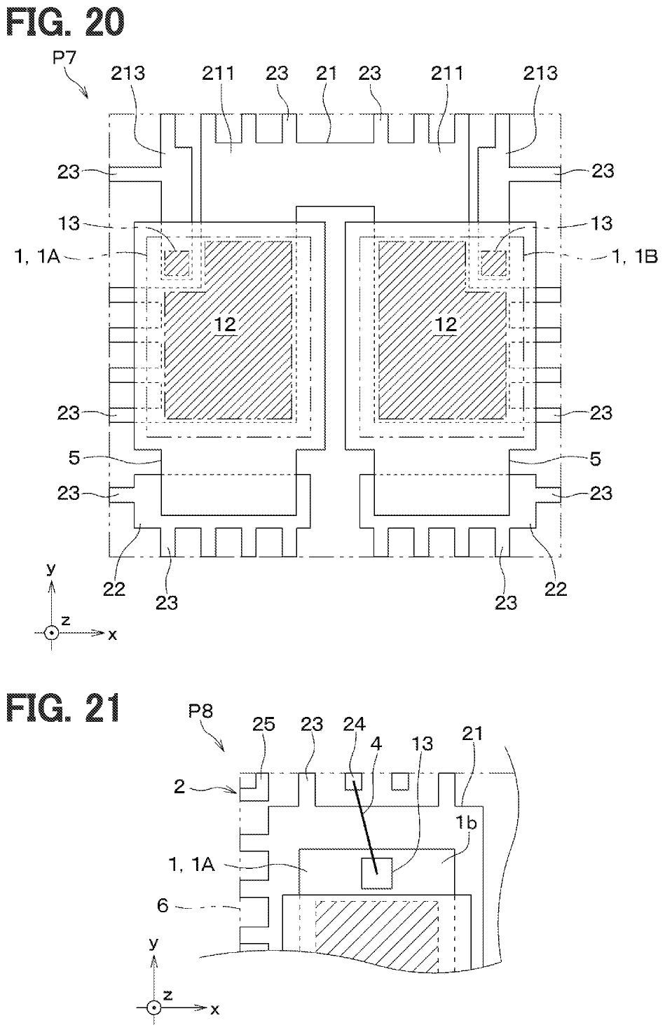

The lead frame 2 is covered with the sealing resin 6. In FIG. 16, a portion of the lead frame 2 covered by the crosslinked member 5 is indicated by a broken line, and the outline of another portion of the lead frame 2 is indicated by a solid line. Although FIG. 16 does not illustrate a cross-sectional view, FIG. 16 illustrates the electrodes 12, 13 of the semiconductor element 1 are hatched. FIG. 16 illustrates that the outline of the sealing resin 6, the outline of the semiconductor element 1, and the outline of each of the electrodes 12, 13 are indicated by a two-dot chain line. The same applies to FIGS. 19 and 20.

The semiconductor package P5 according to the present embodiment is different from the first embodiment, such that the structure of the lead frame 2 and a junction electrode between the semiconductor element 1 and the mounting portion 21 are modified in the present embodiment. Hereinafter, the difference from the first embodiment will be mainly described.

In the present embodiment, the lead frame 2 includes two mounting portions 21, one connected portion 22 and two second element mounting portions 213. Each of the two second element mounting portions 213 is independent of the mounting portion 21 and the connected portion 22, and is connected by the third electrode 13 (gate) of the semiconductor element 1.

In the present embodiment, each of the semiconductor elements 1A, 1B has the electrodes 12, 13 (source, gate) at the first surface 1a on the mounting portion 21 side, and has the first electrode 11 (drain) at the second surface 1b. For example, as illustrated in FIG. 17, in each of the semiconductor elements 1A, 1B, the second electrode 12 at the first surface 1a is joined to the corresponding mounting portion 21 through the joint member 3, and the third electrode 13 is joined to the corresponding mounting portion 21 through the joint member 3. In each of the semiconductor elements 1A, 1B, the corresponding crosslinked member 5 is joined to the first electrode 11 at the corresponding second surface 1b through the joint member 3. In other words, in the semiconductor elements 1A, 1B, the junction electrode between the mounting portion 21 and the crosslinked member 5 is opposite to the one described in each of the first to fourth embodiments.

In other words, in a case where the package structure in which the drain electrode of the semiconductor element 1 mounts on the mounting portion 21 while the source electrode is closer to the top surface 6a of the sealing resin 6 than the drain electrode is defined as a faceup structure, the semiconductor package P5 has a facedown structure that is in an arrangement opposed to the arrangement of the faceup structure.

In the present embodiment, the first mounting portion 21 includes the first element mounting portion 211 and the extension portion 212. The second electrode 12 of the first semiconductor element 1A mounts on the first element mounting portion 211. The extension portion 212 extending from the element mounting portion 211 to the right in the x direction. The crosslinked member 5 is connected to the second semiconductor element 1B. The extension portion 212 is connected by the crosslinked member 5. The semiconductor elements 1A and 1B are connected in parallel through the first mounting portion 21 and the crosslinked member 5, while the semiconductor elements 1A and 1B are thermally coupled through the first mounting portion 21 and the crosslinked member 5.

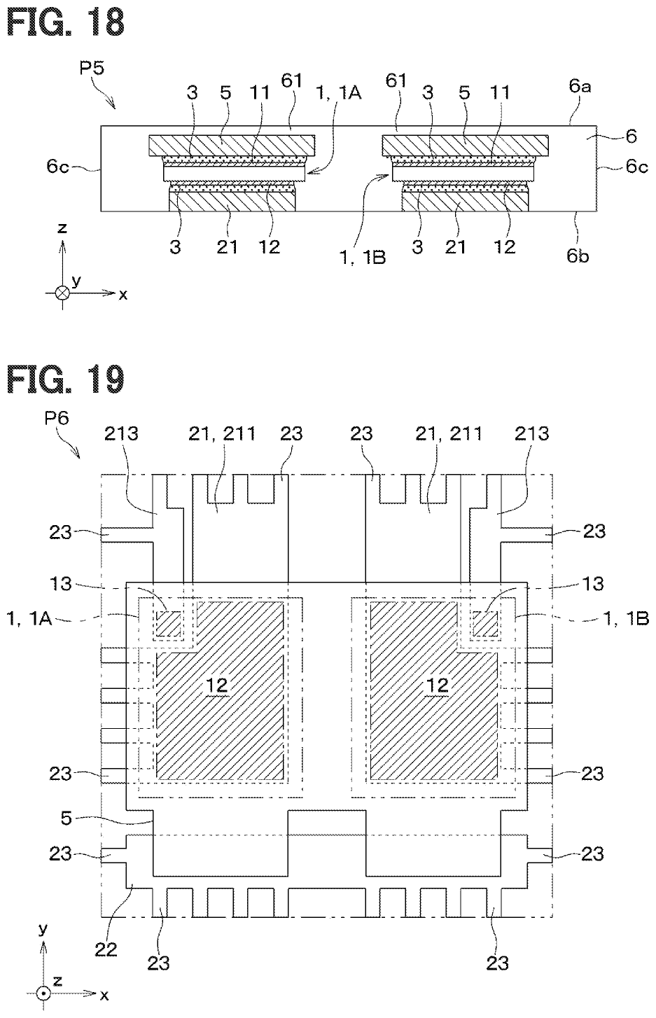

In the present embodiment, for example, as illustrated in FIGS. 17, 18, the crosslinked member 5 is joined to the first electrode 11 of the semiconductor element 1, and the crosslinked member 5 has a larger area than the semiconductor element 1 to cover the whole region of the semiconductor element 1.

The semiconductor elements 1A, 1B are both n-channel transistors in the present embodiment. Although the semiconductor package P5 has the facedown structure, the semiconductor package P5 is included in the half-bridge circuit (see FIG. 11) identical to the second embodiment. Therefore, the semiconductor elements 1A, 1B are not turned on at the same time. In the present embodiment, the second element mounting portion 213 corresponds to the gate terminal (G1, G2); and the first mounting portion 21 corresponds to the source terminal (S1) of the first semiconductor element 1A and the drain terminal (D2) of the second semiconductor element 1B. The connected portion 22 corresponds to the drain terminal (D1) of the first semiconductor element 1A and the power supply terminal, and the second mounting portion 21 corresponds to the source terminal (S2) of the second semiconductor element 1B.

According to the present embodiment, the same advantageous effect as that of each of the first and second embodiments is achieved. Since the crosslinked member 5 covers the entire region of the semiconductor element 1, the effective area of the top surface 6a for heat radiation is larger than the one described in each of the above embodiments so that the enhanced heat radiation at the top surface 6a can be attained in the present embodiment.

### Sixth Embodiment

A semiconductor package P6 according to a sixth embodiment will be described with reference to FIG. 19.

For example, as illustrated in FIG. 19, the semiconductor package P6 according to the present embodiment is different from the first embodiment, such that the structure of each of the lead frame 2 and the crosslinked member 5 and the junction electrode between the semiconductor element 1 and the mounting portion 21 are modified in the present embodiment. Hereinafter, the difference from the first embodiment will be mainly described.

In the present embodiment, the lead frame 2 includes two mounting portions 21 (element mounting portions 211), one connected portion 22, and two second element mounting portions 213. In the lead frame 2, as illustrated in, for example, FIG. 19, the mounting portion 21, the connected portion 22 and the second element mounting portion 213 are arranged symmetrically in the x direction.

As similar to the fifth embodiment, each of the semiconductor elements 1A, 1B has the electrodes 12, 13 (source, gate) at the first surface 1a on the mounting portion 21 side, and has the first electrode 11 (drain) at the second surface 1b. In the present embodiment, the common crosslinked member 5 is connected to the first electrode 11 of each of the second surfaces 1b of the semiconductor elements 1A, 1B, and the semiconductor elements 1A, 1B are electrically connected to the connected portion 22 through the crosslinked member 5.

In the present embodiment, the crosslinked member 5 has a substantially U-shape in a top view, and is connected to the connected portion 22 at two locations. The crosslinked member 5 covers the entire regions of two semiconductor elements 1.

Although the semiconductor package P6 has the facedown structure, the semiconductor package P6 is included in the half-bridge circuit (see FIG. 13) identical to the second embodiment. Therefore, the semiconductor elements 1A, 1B are not turned on at the same time.

In the present embodiment, the first semiconductor element 1A is a p-channel high-side transistor, and the second semiconductor element 1B is an n-channel low-side transistor. The second element mounting portion 213 corresponds to the gate terminal (G1, G2); and the first mounting portion 21 corresponds to the source terminal (S1) of the first semiconductor element 1A and the power supply terminal; and the second mounting portion 21 corresponds to the source terminal (S2) of the second semiconductor element 1B. The connected portion 22 is a connecting portion between the semiconductor elements 1A and 1B. The connected portion 22 corresponds to the drain terminal and output terminal of each of the semiconductor elements 1A, 1B, and the S2 terminal corresponds to the ground (GND) terminal.

According to the present embodiment, the same advantageous effect as that of each of the first and second embodiments is achieved. Since the crosslinked member 5 has a relatively large area as compared with the fifth embodiment, the effective area of the top surface 6a for heat radiation is larger so that the heat radiation at the top surface 6a is further enhanced in the present embodiment.

### Seventh Embodiment

A semiconductor package P7 according to a seventh embodiment will be described with reference to FIG. 20.

For example, as illustrated in FIG. 20, the semiconductor package P7 according to the present embodiment is different from the first embodiment, such that the structure of each of the lead frame 2 and the junction electrode between the semiconductor element 1 and the mounting portion 21 are modified in the present embodiment. Hereinafter, the difference from the first embodiment will be mainly described.

In the present embodiment, the lead frame 2 includes one mounting portion 21, two connected portions 22 and two second element mounting portions 213. In the mounting portion 21 related to the present embodiment, the element mounting portion 211 joined by the second electrode 12 of the first semiconductor element 1A is connected to the element mounting portion 211 joined by the second electrode 12 of the first semiconductor element 1B. The semiconductor elements 1A, 1B are connected in series through the mounting portion 21, and are thermally coupled. In the lead frame 2, the mounting portion 21, the connected portion 22 and the second element mounting portion 213 are arranged symmetrically in the x direction.

Although the semiconductor package P7 has the facedown structure, the semiconductor package P7 is included in the half-bridge circuit (see FIG. 15) identical to the fourth embodiment. Therefore, the semiconductor elements 1A, 1B are not turned on at the same time.

In the present embodiment, the first semiconductor element 1A is an n-channel high-side transistor, and the second semiconductor element 1B is a p-channel low-side transistor. The second element mounting portion 213 corresponds to the gate terminal (G1, G2). The first mounting portion 21 is a connecting portion between the semiconductor elements 1A and 1B, and corresponds to the source terminal (S1, S2) and the output terminal of each of the semiconductor elements 1A, 1B. A portion of the connected portion 22 connected to the first semiconductor element 1A corresponds to the drain terminal (D1) and the power supply terminal, and another portion of the connected portion 22 connected to the second semiconductor element 1B corresponds to the drain terminal (D2).

According to the present embodiment, the same advantageous effect as that of each of the first and second embodiments is achieved. Since the crosslinked member 5 covers the entire region of the semiconductor element 1, the effective area of the top surface 6a for heat radiation is larger than the one described in each of the first to fourth embodiments so that the enhanced heat radiation at the top surface 6a can be attained in the present embodiment.

### Eighth Embodiment

A semiconductor package P8 according to an eighth embodiment will now be described with reference to FIG. 21.

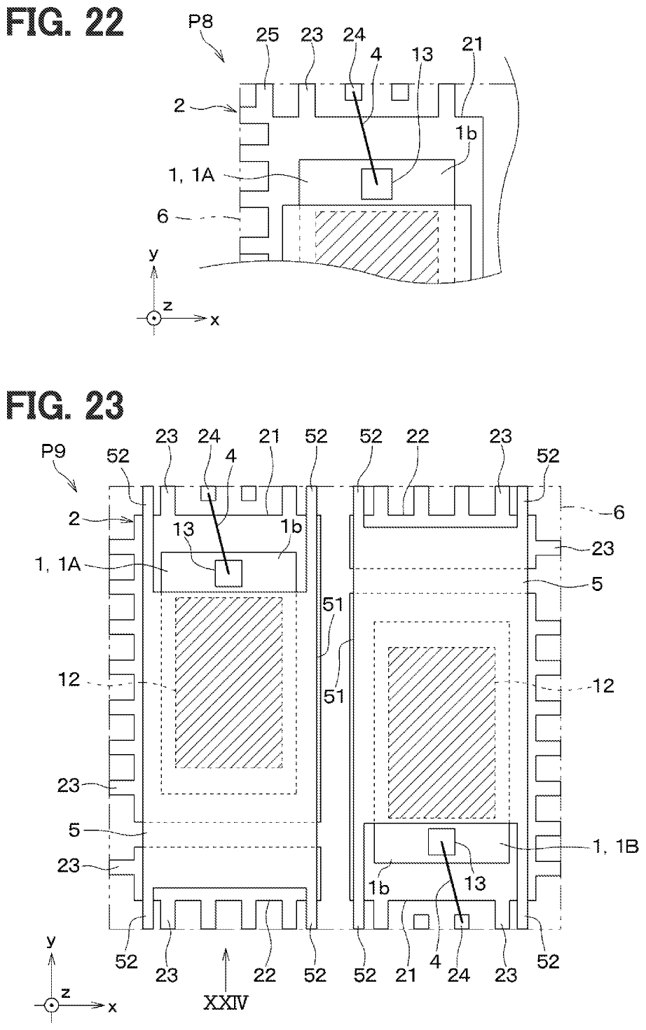

FIG. 21 illustrates a portion of the semiconductor package P8 in the vicinity of a dummy terminal 25 described hereinafter. As similar to FIG. 1, in FIG. 21, the outline of the sealing resin 6 is indicated by a two-dot chain line; and the outline of a portion of the first semiconductor element 1A covered by the crosslinked member 5 and the outline of the second electrode 12 are respectively indicated by broken lines. In FIG. 21, although the cross section is not shown, the second electrode 12 is hatched. The same applies to FIG. 22.

As illustrated in, for example, FIG. 21, the semiconductor package P8 according to the present embodiment is different from the first embodiment such that the lead frame 2 includes the dummy terminal 25 arranged at a corner portion of the sealing resin 6. Hereinafter, the difference from the first embodiment will be mainly described.

In the present embodiment, the lead frame 2 further has the dummy terminal 25 at the corner portion of the sealing resin 6 or in the vicinity of the corner portion of the sealing resin 6. When the semiconductor package P8 mounts on the circuit board 10 or the like, the dummy terminal 25 is a member that functions as a reinforcing terminal. The reinforcing terminal reinforces the joint at the corner portion of the sealing resin 6 and reduces the influence of stress applied to the corner portion of the sealing resin 6.

In a case of the electronic device D1 illustrated in FIG. 4, the heat radiation layer 20 may have the thermal conductivity being 1 W/m·K or larger in view of the thermal conductivity of the sealing resin 6. In this situation, the heat radiation layer 20, for example, the heat radiation gel may have the predetermined thermal conductivity or larger by the adjustment of increasing the content of filler. However, the heat radiation layer 20 may be hardened by such adjustment. The displacement caused by the difference in thermal expansion between the heat radiation member 30 and the circuit board 10 is transmitted to a junction portion between the semiconductor package and the circuit board 10 to cause cracks or the like that may decrease reliability. In a case where multiple semiconductor packages mount on the circuit board 10 and the common heat radiation member 30 is connected to the multiple semiconductor packages through the heat radiation layer 20, the displacement transmitted to the semiconductor packages may become larger due to the arrangement on the circuit board 10.

In the semiconductor package P8, the dummy terminal 25 is disposed at or near the corner portion of the sealing resin 6 where stress is easily concentrated. In the semiconductor package P8, the dummy terminal 25 is exposed to the outside at the bottom surface 6b and the side surface 6c. As a result, the dummy terminal 25 can be joined to the circuit board 10 or the like and the joint strength to the circuit board 10 or the like can be enhanced. Therefore, it is possible to reduce the influence of stress.

As illustrated in, for example, FIG. 22, the dummy terminal 25 may be connected to the mounting portion 21 or the connected portion 22 (not shown). The dummy terminal 25 may be only joined to the circuit board 10 or the like to which the semiconductor package P8 is joined. The dummy terminal 25 may be at an electrical potential independent of other portions of the lead frame 2 or at an electrical potential identical to the other portions of the lead frame 2. For example, the shape and size of the dummy terminal 25 may not be limited to the examples illustrated in FIGS. 21, 22, but may also be modified as appropriate.

According to the present embodiment, the same advantageous effect as that of the first embodiment is achieved. The semiconductor package P8 is provided with the dummy terminal 25. When the semiconductor package P8 mounts on other members, the stress generated in the semiconductor package P8 due to the difference in thermal expansion is reduced. Hence, it is possible to enhance the reliability.

The dummy terminal 25 may be applied to each of the embodiments described in the present disclosure.

### Ninth Embodiment

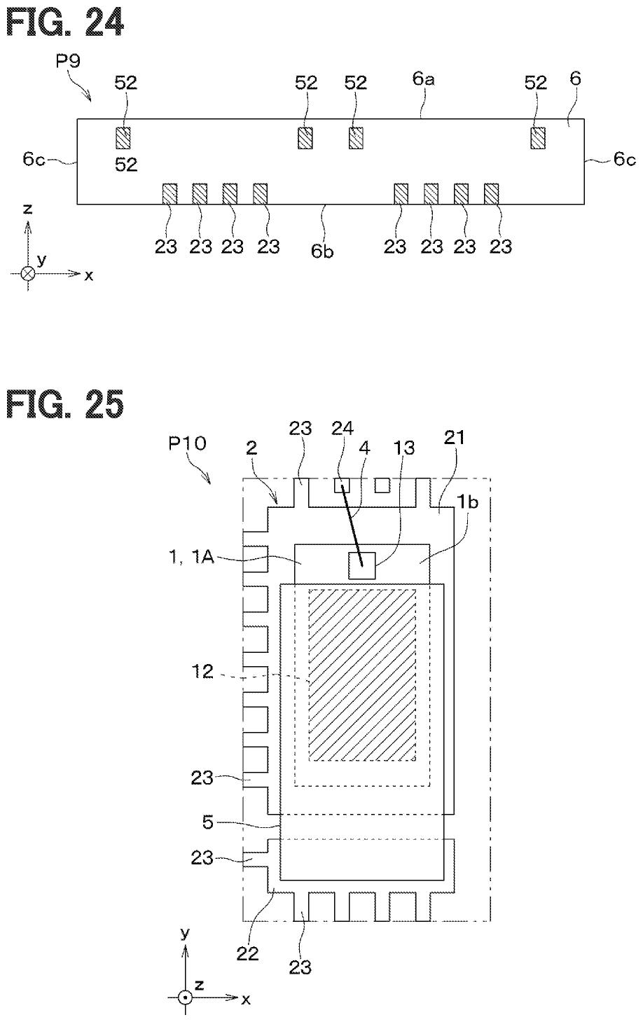

A semiconductor package P9 according to a ninth embodiment will now be described with reference to FIGS. 23, 24.

In FIG. 23, as similar to FIG. 1, the outline of sealing resin 6 is indicated by a two-dot chain line; a portion of an internal structure covered by the sealing resin 6 that is also covered by a crosslinked member 5 is indicated by a broken line; and the outlines of other portions are indicated by a solid line. Although FIG. 23 does not illustrate a cross-sectional view, the second electrode 12 of the semiconductor element 1 is hatched. Although FIG. 24 does not illustrate a cross-sectional view for easier understanding, the first terminal portion 23 exposed from the sealing resin 6 and the extension portion 52 are hatched.

The semiconductor package P9 according to the present embodiment is different from the first embodiment such that the semiconductor package P9 includes an element joint portion 51 and an extension portion 52. The element joint portion 51 is a portion at which the crosslinked member 5 is joined to the semiconductor element 1. The extension portion 52 extends to outside from the element joint portion 51. Hereinafter, the difference from the first embodiment will be mainly described.

In the present embodiment, the crosslinked member 5 includes the element joint portion 51 and the multiple extension portions 52. As illustrated in, for example, FIG. 24, the crosslinked member 5 has multiple extension portions 52 exposed from the sealing resin 6 at the side surface 6c.

The extension portion 52 is provided to prevent the crosslinked member 5 from falling down, when the crosslinked member 5 mounts on the semiconductor element 1. As the area of the crosslinked member 5 is larger than the area of the semiconductor element 1, the proportion of the crosslinked member 5 other than the joint portion with the semiconductor element 1 increases, and the centroid of the crosslinked member 5 shifts. Then, the crosslinked member 5 may lose its balance and fall down when the crosslinked member 5 mounts on the semiconductor element 1.

In the present embodiment, the crosslinked member 5 is provided with the extension portion 52, and is adopted as a portion of the frame member to which multiple crosslinked members 5 are connected until the sealing resin 6 is molded. On the other hand, the lead frame 2 also forms a frame plate member to which multiple lead frames 2 are connected. The semiconductor package P9 is manufactured by: mounting the semiconductor element 1 on the frame plate member; mounting the frame plate member having multiple crosslinked members 5; molding the sealing resin 6 and then dividing the semiconductor package P9 into individual pieces by dicing. The crosslinked member 5 is fixed to the frame member by extension portion 52 until the molding of the sealing resin 6, and the frame member mounts on multiple semiconductor elements. Therefore, the balance can be maintained. When the crosslinked member 5 is cut into individual pieces, the extension portion 52 is cut together with the lead frame 2. Therefore, as illustrated in FIG. 24, the extension portion 52 is exposed to outside at the side surface 6c in the thickness direction of the sealing resin 6.

According to the present embodiment, the same advantageous effect as that of the first embodiment is achieved. When the crosslinked member 5 has the extension portion 52, it is possible to manufacture multiple semiconductor packages P9 at a single time. Even though the area of the crosslinked member 5 is larger than the area of the semiconductor element 1, it is possible to stably mount the crosslinked member 5 on the semiconductor element 1. Since multiple semiconductor packages P9 can be stably manufactured at a single time, it is possible to reduce the manufacturing cost.

### Tenth Embodiment

A semiconductor package P10 according to a tenth embodiment will now be described with reference to FIG. 25.

In FIG. 25 as similar to FIG. 1, the outline of sealing resin 6 is indicated by a two-dot chain line; a portion of an internal structure covered by the sealing resin 6 that is also covered by a crosslinked member 5 is indicated by a broken line, and the outlines of other portions are indicated by a solid line. Although FIG. 23 does not illustrate a cross-sectional view, the second electrode 12 of the semiconductor element 1 is hatched.

The semiconductor package P10 according to the present embodiment is different from the first embodiment, such that one semiconductor element 1 is sealed by the sealing resin 6 and the structure of the lead frame 2 is modified in the present embodiment. Hereinafter, the difference from the first embodiment will be mainly described.

As illustrated in, for example, FIG. 25, the semiconductor package P10 corresponds to the left half of the first embodiment in the x direction. Although the semiconductor package P10 has only the first semiconductor element 1A, the semiconductor package P10 has a top-surface heat radiation structure in which the crosslinked member 5 is connected to the semiconductor element 1. The crosslinked member 5 has a larger width than the semiconductor element 1. Therefore, the effective area of the top surface 6a of the sealing resin 6 becomes larger, and the capability of heat radiation is enhanced.

According to the present embodiment, since the crosslinked member 5 having a larger width than the semiconductor element 1 is arranged while the crosslinked member 5 is not exposed at the top surface 6a, it is possible to manufacture the semiconductor package P10 that can ensure the capability of insulation and the capability of heat radiation at the top surface 6a even though the semiconductor package P10 is miniaturized.

### Other Embodiments

Although the present disclosure has been described in accordance with the embodiments, it is understood that the present disclosure is not limited to such embodiments and structures. The present disclosure encompasses various modifications and variations within the scope of equivalents. In addition, various combinations and modes, and other combinations and modes including only one element, more elements, or less elements are also within the scope and idea of the present disclosure.

For example, each of the first to ninth embodiments describes the semiconductor package having the so-called 2-in-1 structure as an example; however, the present disclosure is not limited to this type of structure. The number of semiconductor elements 1 included in the sealing resin 6 may be three or more. In other words, the semiconductor package may have an N-in-1 structure, where N is equal to or larger than three. When the number of semiconductor elements 1 increases, the volume or area for heat diffusion correspondingly increases in the sealing resin 6. Therefore, it is possible to ensure heat radiation even in the N-in-1 structure.

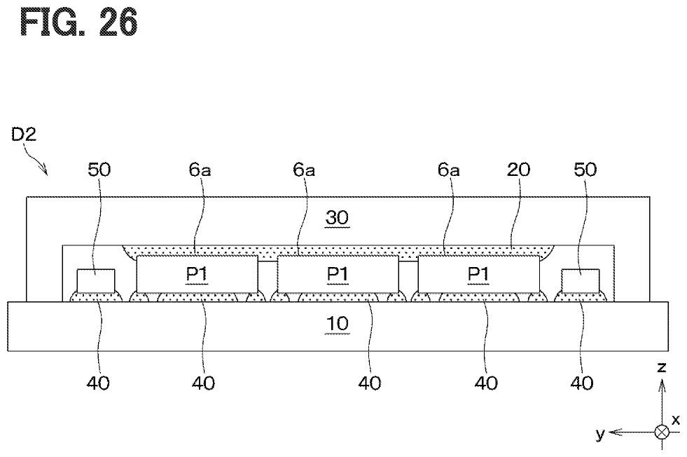

In a case of configuring an electronic device by adopting the semiconductor package in each of the above embodiments, the electronic device is not limited to the electronic device D1 illustrated in FIG. 4. For example, as in an electronic device D2 illustrated in FIG. 26, the semiconductor package and electronic components 50 mount on the circuit board 10, and the heat radiation member 30 covers the semiconductor package and the electronic components 50. In this situation, it may be preferable that the height of each of the semiconductor packages P1 to P10 in the z direction is larger than the height of each of the electronic components 50. When the height of the semiconductor packages P1 to P10 is the largest among the members covered by the heat radiation member 30, it is easy to manage the thickness of the heat radiation layer 20 so that it is possible to reduce the thickness of the heat radiation layer 20 while avoiding contact with other electronic components 50. Therefore, it is not necessary to modify the shape of the heat radiation member 30.

Multiple semiconductor packages P1 to P10 may mount on the circuit board 10, and the number of the semiconductor packages mounting on the circuit board 10 and the arrangement of the semiconductor packages on the circuit board 10 may be modified as appropriate.

What is claimed is:

1. A semiconductor package comprising:
a plurality of semiconductor elements;
a lead frame having
a mounting portion to which a first surface of at least one of the plurality of semiconductor elements is connected, and
a connected portion separated from the mounting portion;
a crosslinked member connected to a second surface of the at least one of the plurality of semiconductor elements and the connected portion, such that the crosslinked member electrically connects the at least one of the plurality of semiconductor elements and the connected portion, the second surface located on a side opposite to the first surface; and
a sealing resin being electrically insulated, the sealing resin covering a portion of the lead frame, the plurality of semiconductor elements, and the crosslinked member, wherein
at least one of the plurality of semiconductor elements is different from another one of the plurality of semiconductor elements in element size or power consumption during drive of the semiconductor package,
each of the plurality of semiconductor elements is a rectangular plate, and
the crosslinked member has a larger width than each of the plurality of semiconductor elements, and covers at least two adjacent corner portions of at least one of the plurality of semiconductor elements.

2. The semiconductor package according to claim 1, wherein the plurality of semiconductor elements are electrically connected through at least one of the mounting portion or the crosslinked member.

3. The semiconductor package according to claim 1, wherein
the at least one of the plurality of semiconductor elements includes two of the plurality of semiconductor elements,
the sealing resin covers the two of the plurality of semiconductor elements,
the two of the plurality of semiconductor elements are transistors, and
the two of the plurality of semiconductor elements are included in a half-bridge circuit in which the two of the plurality of semiconductor elements are connected in series through the mounting portion or the crosslinked member.

4. The semiconductor package according to claim 3, wherein
the mounting portion of the lead frame includes two mounting portions separated from each other,
the two of the plurality of semiconductor elements respectively mount on the two mounting portions,
each of the two of the plurality of semiconductor elements has a drain electrode at the first surface, and has a source electrode and a gate electrode at the second surface, and
one of the two of the plurality of semiconductor elements is a high-side n-channel transistor, and another one of the two of the plurality of semiconductor elements is a low-side n-channel transistor.

5. The semiconductor package according to claim 3, wherein
the mounting portion is a single mounting portion on which the two of the plurality of semiconductor elements mount,
each of the two of the plurality of semiconductor elements has a drain electrode at the first surface, and has a source electrode and a gate electrode at the second surface, and
one of the two of the plurality of semiconductor elements is a high-side p-channel transistor, and another one of the two of the plurality of semiconductor elements is a low-side n-channel transistor.

6. The semiconductor package according to claim 3, wherein
the mounting portion of the lead frame includes two mounting portions separated from each other,
the two of the plurality of semiconductor elements respectively mount on the two mounting portions, while the crosslinked member as a common member is connected to the two of the plurality of semiconductor elements,
each of the two of the plurality of semiconductor elements has a drain electrode at the first surface, and has a source electrode and a gate electrode at the second surface, and
one of the two of the plurality of semiconductor elements is a high-side n-channel transistor, and another one of the two of the plurality of semiconductor elements is a low-side p-channel transistor.

7. The semiconductor package according to claim 3,
the mounting portion of the lead frame includes two mounting portions separated from each other,
the two of the plurality of semiconductor elements respectively mount on the two mounting portions,
each of the two of the plurality of semiconductor elements has a source electrode and a gate electrode at the first surface, and has a drain electrode at the second surface, and
one of the two of the plurality of semiconductor elements is a high-side n-channel transistor, and another one of the two of the plurality of semiconductor elements is a low-side n-channel transistor.

8. The semiconductor package according to claim 3,
the mounting portion of the lead frame includes two mounting portions separated from each other,
the two of the plurality of semiconductor elements respectively mount on the two mounting portions, while the crosslinked member as a common member is connected to the two of the plurality of semiconductor elements,
each of the two of the plurality of semiconductor elements has a source electrode and a gate electrode at the first surface, and has a drain electrode at the second surface, and
one of the two of the plurality of semiconductor elements is a high-side p-channel transistor, and another one of the two of the plurality of semiconductor elements is a low-side n-channel transistor.

9. The semiconductor package according to claim 3, wherein
the mounting portion is a single mounting portion on which the two of the plurality of semiconductor elements mount,
each of the two of the plurality of semiconductor elements has a source electrode and a gate electrode at the first surface, and has a drain electrode at the second surface, and
one of the two of the plurality of semiconductor elements is a high-side n-channel transistor, and another one of the two of the plurality of semiconductor elements is a low-side p-channel transistor.

10. A semiconductor package comprising:
a semiconductor element having a first surface and a second surface located on a side opposite to the first surface, the semiconductor element being a rectangular plate;
a lead frame having
a mounting portion on which the semiconductor element mounts, the mounting portion connected to the first surface of the semiconductor element, and
a connected portion separated from the mounting portion;
a crosslinked member connected to the second surface of the semiconductor element and the connected portion to electrically connect the semiconductor element and the connected portion; and
a sealing resin being electrically insulated, the sealing resin covering a portion of the lead frame, the semiconductor element, and the crosslinked member,
wherein the crosslinked member has a larger width than the semiconductor element, and covers at least two adjacent corner portions of the semiconductor element.

11. The semiconductor package according to claim 1, wherein
the sealing resin includes has a side surface in a thickness direction of the mounting portion as one of a plurality of outer surfaces of the sealing resin, and
a portion of the crosslinked member is exposed to outside of the sealing resin at the side surface of the sealing resin.

12. The semiconductor package according to claim 1, wherein at least one of the plurality of semiconductor elements is connected to an external power supply having a voltage of 60 volts or lower, such that at least one of the plurality of semiconductor elements is driven by the voltage of 60 volts or lower through the external power supply.

13. The semiconductor package according to claim 1, wherein
a surface of the mounting portion on which at least one of the plurality of semiconductor elements mounts is defined as a mounting surface,
the sealing resin covers a plurality of members including the crosslinked member,
a distance from a top of each of the plurality of members to the mounting surface in a direction normal to the mounting surface is defined as a height of each of the plurality of members, and
the crosslinked member has a largest height among the plurality of members covered by the sealing resin.

14. The semiconductor package according to claim 1, wherein
the sealing resin has a surface layer portion covering at least the crosslinked member, and
thermal conductivity of the surface layer portion is equal to 2.2 watts per meter-kelvin or larger.

15. An electronic device comprising:
a semiconductor package including
a plurality of semiconductor elements being different in element size or power consumption during drive of the semiconductor package,
a lead frame having
a mounting portion to which a first surface of at least one of the plurality of semiconductor elements is connected, and
a connected portion separated from the mounting portion,
a crosslinked member connected to a second surface of the at least one of the plurality of semiconductor elements and the connected portion, such that the crosslinked member electrically connects the at least one of the plurality of semiconductor elements and the connected portion, the second surface located on a side opposite to the first surface, and
a sealing resin being electrically insulated, the sealing resin covering a portion of the lead frame, the plurality of semiconductor elements, and the crosslinked member;
a circuit board on which the semiconductor package mounts;
a heat radiation member disposed on a side opposite to the circuit board to sandwich the semiconductor package between the heat radiation member and the circuit board, such that the heat radiation member diffuses heat to outside; and
a heat radiation layer disposed at a top surface of the sealing resin facing the heat radiation member, the top surface being a surface of the sealing resin on a side covering the crosslinked member, a gap between the semiconductor package and the heat radiation member being filled with the heat radiation layer, wherein
each of the plurality of semiconductor elements is a rectangular plate, and
the crosslinked member has a larger width than each of the plurality of semiconductor elements, and covers at least two adjacent corner portions of at least one of the plurality of semiconductor elements.

16. The electronic device according to claim 15, wherein
the semiconductor package includes a plurality of semiconductor packages, and
the heat radiation member covers the plurality of semiconductor packages.

17. The electronic device according to claim 15, wherein
the semiconductor package is one of a plurality of electronic components mounting on the circuit board,
a height of the sealing resin is a distance between the top surface of the sealing resin and the circuit board, and
the height of the sealing resin is largest among the plurality of electronic components.

18. The electronic device according to claim 15, wherein
a bottom surface of the sealing resin on a side opposite to the top surface is joined to the circuit board in the semiconductor package, and
the heat radiation member has larger thermal conductivity than the circuit board.
